(19) United States
(12) Patent Application Publication
(10) Pub. No.: US 2021/0036205 A1
(43) Pub. Date: Feb. 4, 2021

(54) THERMOELECTRIC GENERATION APPARATUS

(71) Applicant: SANGO Co., Ltd., Miyoshi-shi, Aichi (JP)

(72) Inventors: Takashi KATOU, Miyoshi-shi, Aichi (JP); Takeshi SUMITA, Miyoshi-shi, Aichi (JP)

(73) Assignee: SANGO Co., Ltd., Miyoshi-shi, Aichi (JP)

(21) Appl. No.: 16/964,078

(22) PCT Filed: Nov. 6, 2018
(86) PCT No.: PCT/JP2018/041121

§ 371 Date: Jul. 22, 2020

(30) Foreign Application Priority Data
Jan. 24, 2018 (JP) 2018-009765

(51) Int. Cl. H01L 35/32; H02N 11/00; H01L 35/30; H02M 3/155

(52) U.S. Cl. CPC H01L 35/32; H02M 3/155; H01L 35/30; H02N 11/002

(57) ABSTRACT

A thermoelectric generation apparatus comprises a thermoelectric generation module, an output adjustment device and a control part. The thermoelectric generation module includes a thermoelectric conversion element which generates electricity by a temperature difference between a high temperature heat source and a low temperature heat source. The output adjustment device changes an output current value that is magnitude of electric current output from the thermoelectric generation module and/or an output voltage value that is magnitude of electric voltage output from the thermoelectric generation module. The control part controls the output adjustment device to control the output current value and/or the output voltage value. The control part lowers a high temperature side interface temperature by controlling the output adjustment device to increase the output current value or decrease the output voltage value when a high temperature side interface temperature is judged to be higher than a predetermined upper limit temperature.

### TECHNICAL FIELD

The present invention relates to a thermoelectric generation apparatus. More specifically, the present invention relates to a thermoelectric generation apparatus which can work at high generating efficiency while preventing damage of a thermoelectric conversion element.

### BACKGROUND ART

For example, in technical fields of temperature adjustment and waste-heat usage and so on, thermoelectric conversion elements, such as a Peltier element which converts electric energy into thermal energy using Peltier effect, and a Seebeck element which converts thermal energy into electric energy using Seebeck effect, have been expected to be utilized. In particular, from a viewpoint of saving energy, a thermoelectric generation apparatus which converts waste heat from heat sources, such as an internal combustion engine, for example, into electricity using a thermoelectric conversion element has been developed actively.

A thermoelectric conversion element is constituted by a joined body of different kinds of metal or of semiconductor, and performs energy conversion between electric energy and thermal energy. Typically, a combination of p type thermoelectric semiconductor and n type thermoelectric semiconductor is used as a thermoelectric conversion element, and outputs electric power (generates electricity) of magnitude (an output power value P) corresponding to magnitude of a heat source temperature difference ΔTs that is a temperature difference between a high temperature heat source 10H and a low temperature heat source 10C.

Generally, a thermoelectric conversion element is constituted as what is called a “thermoelectric generation module” which includes a combination of two different kinds of thermoelectric semiconductor, two support substrates which oppose to each other and sandwich the combination and electrodes which are formed on opposing surfaces of these two support substrates and electrically connect the combination. In a thermoelectric generation module, for the purpose of obtaining larger output power, for example, a plurality of thermoelectric conversion elements may be electrically connected in series by arranging two different kinds of thermoelectric conversion elements between the above-mentioned two support substrates in a grid pattern and electrically connecting them alternately in series. Moreover, for the purpose of obtaining much larger output power, for example, what is called a “thermoelectric generation unit” having a configuration, in which a plurality of thermoelectric generation modules are electrically connected in series, etc. is also widely adopted in a thermoelectric generation apparatus.

The thermoelectric generation apparatus which has a configuration as mentioned above generates electric power corresponding to magnitude of a temperature difference between a high temperature heat source and a low temperature heat source (heat source temperature difference). For example, generally, the output power value P from the thermoelectric generation module becomes larger as the heat source temperature difference ΔTs becomes larger as shown in a graph of FIG. 1, for example, unless problems, such as damage of a thermoelectric conversion element, arise.

Moreover, the output power value P from the thermoelectric generation module at a fixed heat source temperature difference ΔTs changes in accordance with an output current value I from the thermoelectric generation module. Specifically, as shown in the graph of FIG. 2, for example, the output power value P from the thermoelectric generation module becomes the maximum value (maximum output power value Pp) at a specific output current value Ip. In other words, the output power value P becomes larger as the output current value I becomes larger in a region where the output current value I is less than this specific output current value Ip, and the output power value P becomes smaller as the output current value I becomes larger in a region where the output current value I is this specific output current value Ip or more.

Furthermore, a relation between the output current value I and the output power value P as the above changes in accordance with magnitude of the heat source temperature difference ΔTs, the specific output current value Ip at which the maximum output power value Pp is acquired and the maximum output power value Pp acquired at the specific output current value Ip also change in accordance with the magnitude of the heat source temperature difference ΔTs. Generally, as shown in a graph of FIG. 3, for example, the specific output current value Ip becomes larger in an order of Ip1, Ip2 and Ip3 and the maximum output power value Pp becomes larger in an order of Pp1, Pp2 and Pp3, as the heat source temperature difference ΔTs becomes larger in an order of ATs1, ATs2 and ATs3. Therefore, in order to always acquire the maximum output power value Pp in the thermoelectric generation apparatus, it is necessary to adjust the output current value I in accordance with the magnitude of the heat source temperature difference ΔTs at each occasion (refer to the Patent Document 1 (PTL1), for example).

Similarly to the above, the output power value P from the thermoelectric generation module at a fixed heat source temperature difference ΔTs changes in accordance with the output voltage value V from thermoelectric generation module. Specifically, as shown in a graph of FIG. 4, for example, the output power value P from the thermoelectric generation module becomes the maximum value (maximum output power value Pp) at a specific output voltage value Vp. In other words, the output power value P becomes larger as the output voltage value V becomes larger in a region where the output voltage value V is less than this specific output current value Vp, and the output power value P becomes smaller as the output voltage value V becomes larger in a region the output voltage value V is this specific output voltage value Vp or more.

Furthermore, a relation between the output voltage value V and the output power value P as the above changes in accordance with magnitude of the heat source temperature difference ΔTs, and the specific output voltage value Vp at which the maximum output power value Pp is acquired and the maximum output power value Pp acquired at the specific output voltage value Vp also changes in accordance with the magnitude of the heat source temperature difference ΔTs. Generally, as shown in a graph of FIG. 5, for example, the specific output voltage value Vp becomes smaller in an order of Vp1, Vp2 and Vp3 and the maximum output power value Pp becomes larger in an order of Pp1, Pp2 and Pp3, as the heat source temperature difference ΔTs becomes larger in an order of ΔTs1, ΔTs2 and ΔTs3. Therefore, in order to always acquire the maximum output power value Pp in the thermoelectric generation apparatus, it is necessary to adjust the output voltage value V in accordance with the magnitude of the heat source temperature difference ΔTs at each occasion

In addition, in the art, a control method in which output current or output voltage from a power generation module, such as a solar cell, is adjusted by a charge controller or a power conditioner (converter), etc. to extract the maximum electric power, has been known. As a specific example of such a control procedure, a “maximum power point tracking” (MPPT) can be mentioned.

The maximum power point tracking (MPPT) is a method in which the output power value P is maximized by gradually increasing the output current value I from the power generation module through electric current control of a controller and further increasing the output current value I when the output power value P increases in connection with this while reducing the output current value I when the output power value P decreases conversely, for example. When such MPPT is applied to a thermoelectric generation apparatus, as a result, like the invention described in the Patent Document 1 (PTL1), the maximum output power value Pp can be acquired from the thermoelectric generation module by adjusting the output current value I in accordance with magnitude of the heat source temperature difference ΔTs.

By the way, as explained referring to the graph of FIG. 1, the output power value P from the thermoelectric generation module becomes larger, as the heat source temperature difference ΔTs that is a temperature difference between the high temperature heat source 10H and the low temperature heat source 10C becomes larger. Therefore, in order to raise generating efficiency, it is desirable to make the thermoelectric generation apparatus operate at as large heat source temperature difference ΔTs as possible, as long as a high temperature side interface temperature Tbh that is a temperature of a high temperature side interface Bh that is an interface on the high temperature heat source side of the thermoelectric conversion element does not exceed an upper limit (upper limit temperature Tmax) determined in accordance with a heat resistance limit of the thermoelectric conversion element, etc., for example. Typically, it is desirable to make the thermoelectric generation apparatus operate while maintaining the high temperature side interface temperature Tbh of the thermoelectric conversion element close to the upper limit temperature Tmax. However, for example, depending on a supply source of the high temperature heat source and/or an operational state of the thermoelectric generation apparatus, there is a possibility that the high temperature side interface temperature Tbh may become higher than the upper limit temperature Tmax to lead to problems, such as damage of the thermoelectric conversion element, for example.

Countermeasures as follow can be considered against the problems as the above.

Countermeasure 1: The thermoelectric generation apparatus operate is made to operate while always maintaining the high temperature side interface temperature Tbh at a temperature a predetermined temperature width lower than the upper limit temperature Tmax.

Countermeasure 2: The high temperature side interface Bh that is an interface on the high temperature heat source side of the thermoelectric conversion element is cooled by heat dissipation when the high temperature side interface temperature Tbh is likely to become higher than the upper limit temperature Tmax.

However, in accordance with the above-mentioned countermeasure 1, since the high temperature side interface temperature Tbh is always the predetermined temperature width lower than the upper limit temperature Tmax, a “critical output power value Pmax” that is the maximum output power value Pp acquired when the high temperature side interface temperature Tbh is equal to the upper limit temperature Tmax cannot be acquired. On the other hand, in accordance with the above-mentioned countermeasure 2, a means for heat dissipation (for example, a cooling device, etc.) must be added, and there is a possibility to cause complication, enlargement and cost increase of a thermoelectric generation apparatus. Moreover, since quantity of heat which the thermoelectric conversion element holds is decreased by heat dissipation, a time period required for heating the high temperature side interface again to bring the high temperature side interface temperature Tbh close to the upper limit temperature Tmax and increase the output power value P becomes longer when the high temperature side interface temperature Tbh becomes sufficiently lower than the upper limit temperature Tmax.

As the above, in the art, a thermoelectric generation apparatus which can work at high generating efficiency while preventing damage of a thermoelectric conversion element has been demanded.

### CITATION LIST

### Patent Literature

[PTL1] Japanese Patent Application Laid-Open (kokai) No. H06-22572

### SUMMARY OF INVENTION

### Technical Problem

As mentioned above, in the art, a thermoelectric generation apparatus which can work at high generating efficiency while preventing damage of a thermoelectric conversion element has been demanded.

### Solution to Problem

In light of the above-mentioned subject, as a result of wholehearted research, the present inventor has found out that a high temperature side interface temperature of a thermoelectric conversion element can be lowered quickly and effectively by utilizing a phenomenon that a thermal conductivity of a thermoelectric conversion element becomes larger and movement of heat to an interface on a side of a low temperature heat source from an interface on a side of a high temperature heat source of the thermoelectric conversion element is promoted when electric current which flows through the thermoelectric conversion element is increased.

Then, a thermoelectric generation apparatus according to the present invention (which may be referred to as a “present invention apparatus” hereafter) is a thermoelectric generation apparatus comprising a thermoelectric generation module 10M, an output adjustment device 30 and a control part Uc. The thermoelectric generation module 10M comprises a thermoelectric conversion element 10E which generates electricity by a heat source temperature difference ΔTs that is a temperature difference between a high temperature heat source 10H and a low temperature heat source 10C. The output adjustment device 30 changes an output current value I that is magnitude of electric current output from the thermoelectric generation module 10M and/or an output voltage value V that is magnitude of electric voltage output from the thermoelectric generation module 10M. The control part Uc controls the output adjustment device 30 to control the output current value I and/or the output voltage value V.

Moreover, the present invention apparatus further comprises a temperature detection device 40 which detects a temperature measuring point temperature Tm that is a temperature of a temperature measuring point Dm that is at least one position included in any of the high temperature heat source 10H, the low temperature heat source 10C and the thermoelectric generation module 10M. Furthermore, in the present invention apparatus, the control part Uc is configured so as to control the output adjustment device 30 to increase the output current value I or decrease the output voltage value V when a high temperature side interface temperature Tbh is judged to be higher than a predetermined upper limit temperature Tmax at least based on the temperature measuring point temperature Tm. The high temperature side interface temperature Tbh is a temperature of a high temperature side interface Bh that is an interface on the high temperature heat source 10H side of the thermoelectric conversion element 10E.

As will be mentioned in detail later, a judgment whether the high temperature side interface temperature Tbh is higher than the predetermined upper limit temperature Tmax or not at least based on the temperature measuring point temperature Tm can be carried out with various procedures. For example, the high temperature side interface temperature Tbh can be determined based on a difference between a temperature of the temperature measuring point Dm (temperature measuring point temperature Tm) and a temperature of another position, a thermal conductivity λm and heat passage area Am of a region between these two positions, and a penetrating heat quantity W determined based on a distance Lm between these two positions, a thermal conductivity Abhm and heat passage area Abhm of a region between the temperature measuring point Dm and the high temperature side interface Bh, the temperature measuring point temperature Tm and a distance Lbhm between the temperature measuring point Dm and the high temperature side interface Bh. For example, as the above-mentioned “temperature of another position”, a temperature of another temperature measuring point or a temperature of the low temperature heat source 10C, etc. can be adopted.

Alternatively, the present invention apparatus can further comprise an output detection device 20. The output detection device 20 detects output related values Mout that are a set of a plurality of detection values consisting of an output power value P that is magnitude of electric power output from the thermoelectric generation module 10M, an output current value I that is magnitude of electric current output from the thermoelectric generation module 10M and/or an output voltage value V that is magnitude of electric voltage output from the thermoelectric generation module 10M. In this case, the control part Uc can have previously stored first characteristic data that is data representing a relation between the heat source temperature difference ΔTs and the output related values Mout. And, the control part Uc can be configured so as to judge whether the high temperature side interface temperature Tbh is higher than the upper limit temperature Tmax or not based on the output related values Mout detected by the output detection device 20 and the above-mentioned first characteristic data. As will be mentioned later in detail, the judgment can also be carried out in accordance with various procedures.

Furthermore, in the present invention apparatus, the control part Uc may be configured so as to perform output maximize control in which the output adjustment device 30 is controlled to change the output current value I and/or the output voltage value V such that the output power value P becomes the maximum, when the high temperature side interface temperature Tbh is judged to be the upper limit temperature Tmax or less. In this case, as will be mentioned later in detail, an arithmetic processing load for judging whether the high temperature side interface temperature Tbh is higher than the upper limit temperature Tmax or not can be reduced.

### Advantageous Effects of Invention

In the present invention apparatus, as mentioned above, the control part Uc is configured so as to control the output adjustment device 30 to increase the output current value I or decrease the output voltage value V when the high temperature side interface temperature Tbh is judged to be higher than the predetermined upper limit temperature Tmax. Thereby, since the high temperature heat source side interface temperature Tbh of the thermoelectric conversion element 10E can be lowered quickly and effectively, the thermoelectric generation apparatus can be made to operate at high generating efficiency while preventing damage of the thermoelectric conversion element 10E.

Other objectives, other features and accompanying advantages of the present invention will be easily understood from the following explanation of embodiments of the present invention, which will be described referring to drawings.

### BRIEF DESCRIPTION OF DRAWINGS

FIG. 1 is a schematic graph for showing a relation between the output power value P and the heat source temperature difference ΔTs from the thermoelectric generation module.

FIG. 2 is a schematic graph for showing a relation between the output power value P and the output current value I from the thermoelectric generation module when the heat source temperature difference, ΔTs is constant.

FIG. 3 is a schematic graph for showing that a relation between the output current value I and the output power value P from the thermoelectric generation module changes in accordance with the magnitude of the heat source temperature difference, ΔTs.

FIG. 4 is a schematic graph for showing a relation between the output power value P and the output voltage value V from the thermoelectric generation module when the heat source temperature difference ΔTs is constant.

FIG. 5 is a schematic graph for showing that a relation between the output voltage value V and the output power value P from the thermoelectric generation module changes in accordance with the magnitude of the heat source temperature difference ΔTs.

FIG. 6 is a schematic view for showing an example of a configuration of a thermoelectric generation apparatus an according to a first embodiment of the present invention (first apparatus).

FIG. 7 is a schematic partial sectional view of a high temperature heat source, a low temperature heat source and a thermoelectric generation module constituting the first apparatus.

FIG. 8 is a schematic graph for showing that the high temperature heat source side interface temperature Tbh of the thermoelectric conversion element falls in accordance with increase of the output current value I from the thermoelectric generation module.

FIG. 9 is a flowchart for showing an example of a high temperature side interface temperature control routine performed by thermoelectric generation apparatus according to the first embodiment of the present invention (first apparatus).

FIG. 10 is a schematic graph for showing that the relation between the output current value I and the output power value P from the thermoelectric generation module changes with the magnitude of heat source temperature difference ΔTs.

FIG. 11 is a schematic graph for showing a region where plots corresponding to the output related values Mout in various states may exist with respect to a reference curve CS representing a relation between the output power value P and the output current value I when the heat source temperature difference ΔTs is equal to the upper limit heat source temperature difference ΔTmax (namely, when the high temperature side interface temperature Tbh is equal to the upper limit temperature Tmax) in a case where the low temperature heat source temperature Tc is maintained at a constant temperature.

FIG. 12 is a schematic graph for explaining that the upper limit output power value Pmax is determined based on the first characteristic data from the output current value I at a certain time point in a thermoelectric generation apparatus according to a seventh embodiment of the present invention (seventh apparatus).

FIG. 13 is a schematic graph for explaining that the upper limit output related values Mmax is determined based on the first characteristic data from the output power value P at a certain time point in a thermoelectric generation apparatus according to an eighth embodiment of the present invention (eighth apparatus).

FIG. 14 is a schematic view for showing a configuration of a thermoelectric generation apparatus as a specific example of the present invention apparatus (working example apparatus 101).

FIG. 15 is a schematic enlarged view for showing a region A surrounded by a broken line in FIG. 14, in which a vicinity of positions where two thermocouples are disposed in the low temperature heat source is shown.

FIG. 16 is a schematic graph for explaining alterations of the output current value I and the output power value P in control of the high temperature side interface temperature Tbh performed in a thermoelectric generation apparatus as another specific example of the present invention apparatus (working example apparatus 102).

FIG. 17 is a schematic time chart for explaining alterations of the temperature of respective positions in the working example apparatus 102 in the control of the high temperature side interface temperature Tbh performed in the working example apparatus 102.

### DESCRIPTION OF EMBODIMENTS

### First Embodiment

Hereafter, a thermoelectric generation apparatus according to a first embodiment of the present invention (which may be referred to as a “first apparatus” hereafter) will be explained.

<Configuration>

The first apparatus is a thermoelectric generation apparatus which comprises a thermoelectric generation module, an output adjustment device and a control part. FIG. 6 is a schematic view for showing an example of a configuration of the first apparatus. The first apparatus 100 comprises a thermoelectric generation module 10M, an output adjustment device 30 and a control part Uc. The thermoelectric generation module 10M comprises a thermoelectric conversion element which is interposed between a high temperature heat source 10H and a low temperature heat source 10C and generates electricity by a heat source temperature difference ΔTs that is a temperature difference between the high temperature heat source 10H and the low temperature heat source 10C.

The heat source temperature difference ΔTs is a temperature difference between the high temperature heat source 10H and the low temperature heat source 10C, and more specifically it is a difference between a temperature at an arbitrary position in the high temperature heat source 10H and a temperature at an arbitrary position in the low temperature heat source 10C. Typically, the heat source temperature difference ΔTs is a difference between a temperature at an interface on the thermoelectric generation module side of the high temperature heat source 10H and a temperature at an interface on the thermoelectric generation module side of the low temperature heat source 10C.

A configuration of the thermoelectric generation module 10M is not limited in particular, as long as it is possible to generate electricity by the heat source temperature difference ΔTs that is a temperature difference between the high temperature heat source 10H and the low temperature heat source 10C. Typically, the thermoelectric generation module 10M comprises a pair of support substrates opposing to each other, electrodes formed respectively at predetermined positions on opposing surfaces of the one pair of the support substrates, two different kinds of thermoelectric semiconductors and two electrode members.

A shape and size of the above-mentioned support substrates can be properly determined according to the intended use of the first apparatus 100, etc., for example. Moreover, the above-mentioned electrodes are constituted by good conductor (for example, copper, etc.) and joined to a thermoelectric semiconductor by soldering, for example. Typically, the above-mentioned one pair of the support substrates is a kind of what is called “circuit boards.”

Material and configuration of the two different kinds of the thermoelectric semiconductors can also be properly chosen according to magnitude of a thermoelectric effect demanded in the intended use of the first apparatus 100, etc., for example. Specifically, a combination of a p type thermoelectric semiconductor (for example, Bi_{1.5}Sb_{0.5}Te₃, etc.) and an n type thermoelectric semiconductor (for example, Bi₂Te₃, etc.) can be used.

Number of the thermoelectric semiconductors 10P and 10N built into the thermoelectric generation module 10M is properly determined according to the magnitude of the thermoelectric effect demanded in the intended use of the first apparatus 100, etc., for example. It is common that a thermoelectric generation module includes a plurality of sets of two different kind of thermoelectric semiconductors for the purpose of achievement of a larger thermoelectric effect, etc. A plurality of the two different kinds of thermoelectric semiconductors is electrically connected alternately in series to form a series electric circuit.

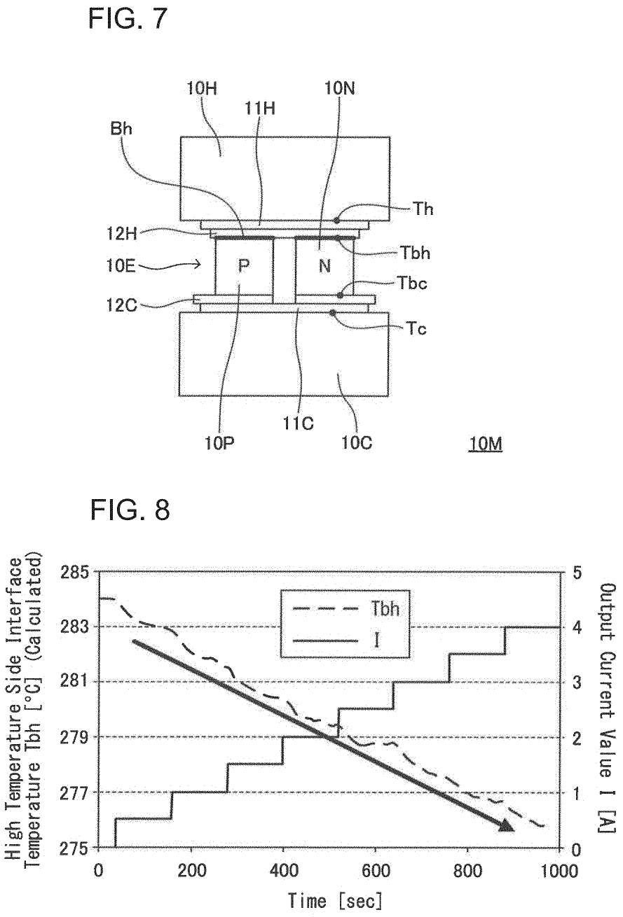

Specifically, as shown in FIG. 7, for example, one thermoelectric conversion element 10E is constituted by two different kinds of thermoelectric semiconductors 10P and 10N electrically connected through an electrode 12H formed on one substrate 11H among a pair of support substrates 11H and 11C. Namely, the thermoelectric conversion element 10E has what is called “π(pi) type” architecture. A plurality of the thermoelectric conversion element 10E constituted in this way is conducted (electrically connected) in the same direction through the electrode 12C formed on the other substrate 11C among the one pair of the substrates. Namely, a plurality of the two different kinds of the thermoelectric semiconductors 10P and 10N is electrically connected alternately in series by the above-mentioned electrodes 12H and 12C to form a series electric circuit.

In addition, from a viewpoint of weight reduction and/or miniaturization of the first apparatus 100, it is desirable to arrange more thermoelectric semiconductors 10P and 10N densely (namely, at as small intervals as possible) between smaller support substrates 11H and 11C. Therefore, in the thermoelectric generation module 10M, it is common that a plurality of the two different kinds of the thermoelectric semiconductors 10P and 10N is sandwiched between the one pair of the support substrates 11H and 11C and arranged so as to be in a grid-like array.

Moreover, the thermoelectric generation module 10M can also be constituted as a thermoelectric generation unit including a plurality of the thermoelectric generation modules 10M electrically connected in series for the purpose of achievement of a much larger thermoelectric effect, etc.

Furthermore, two electrode members (not shown) are constituted such that both ends of the series electric circuit formed as mentioned above are conducted with outside. The “outside” mentioned herein means an apparatus other than the thermoelectric generation module 10M, such as an other apparatus to which power output by the thermoelectric generation module 10M is supplied, an other thermoelectric generation module which constitutes the thermoelectric generation unit including the thermoelectric generation module 10M, and an other apparatus to which power output by the thermoelectric generation unit including the thermoelectric generation module 10M is supplied, etc., for example.

Referring to FIG. 6 again here, the output adjustment device 30 changes the output current value I that is magnitude of the electric current output from the thermoelectric generation module 10M and/or the output voltage value V that is magnitude of electric voltage output from the thermoelectric generation module 10M. A configuration of the output adjustment device 30 is not limited in particular, as long as it is possible to change the output current value I and/or the output voltage value V. As a specific example of such an output adjustment device 30, an apparatus such as a DC-DC converter which can adjust the output current value I and/or the output voltage value V from the thermoelectric generation module 10M, can be mentioned, for example. For example, when the first apparatus 100 is used as a charging apparatus for charging a secondary cell, apparatuses such as a charge controller or a power conditioner (converter) having function to adjust the output current value I and/or the output voltage value V from the thermoelectric generation module 10M can be used as the output adjustment device 30.

The control part Uc controls the output adjustment device 30 to control the output current value I and/or the output voltage value V. A configuration of the control part Uc is not limited in particular, as long as it is possible to control the output adjustment device 30 to control the output current value I and/or the output voltage value V. As a specific example of such a control part Uc, an electronic control unit (ECU) which has, as a main component, a microcomputer comprising a CPU, an ROM, an RAM and an interface, etc. can be mentioned, for example. The CPU controls the output adjustment device to control the output current value I and/or the output voltage value V by performing instructions (routine) stored in a memory (ROM).

In addition, the control part Uc may be implemented as an independent component separated from other components constituting the first apparatus 100, or functions as the control part Uc may be realized in an ECU which another component constituting the first apparatus 100 comprises, etc. Furthermore, the functions as the control part Uc do not need to be realized in one component, and the functions as the control part Uc may be realized as a whole by processing performed in a plurality of components. In the example shown in FIG. 6, the functions as the control part Uc are realized by an ECU which the output adjustment device 30 comprises.

In accordance with the configuration as mentioned above, the first apparatus 100 can stably supply the output power from the thermoelectric generation module 10M to a load, such as a secondary cell and an electronic equipment, for example. In the example shown in FIG. 6, a power supply destination 200 as such a load is connected to an output side of the output adjustment device 30. However, as mentioned above, a possibility that the high temperature side interface temperature Tbh may become higher than the predetermined upper limit temperature Tmax and lead to problems such as damage of the thermoelectric conversion element 10E, for example, may be increased, depending on a source of the high temperature heat source 10H and/or an operational state of the thermoelectric generation apparatus.

In the case as mentioned above, it can be conceived to cool the high temperature side interface Bh that is an interface on the high temperature heat source 10H side of the thermoelectric conversion element 10E (a part shown by a bold solid line in FIG. 7) by heat dissipation like the above-mentioned countermeasure 2. However, it is essential to add a means for heat dissipation (heat dissipation means) in order to execute such a countermeasure, and there is a possibility to cause complication, enlargement and cost increase of the first apparatus 100. Moreover, since quantity of heat which the thermoelectric conversion element holds is decreased by heat dissipation, a time period required for heating the high temperature side interface Bh again to bring the high temperature side interface temperature Tbh close to the upper limit temperature Tmax and increase the output power value P becomes longer when the high temperature side interface temperature Tbh becomes sufficiently lower than the upper limit temperature Tmax.

However, as mentioned above, when electric current which flows through the thermoelectric conversion element is increased, a thermal conductivity of the thermoelectric conversion element 10E becomes larger and movement of heat to the low temperature heat source 10C from the high temperature heat source 10H, and the high temperature side interface temperature Tbh of the thermoelectric conversion element 10E can be lowered quickly and effectively. Specifically, when the output current value I is gradually increased with the lapse of time as shown in FIG. 8, for example, the high temperature side interface temperature Tbh of the thermoelectric conversion element 10E falls accordingly (refer to an arrow in the graph).

Therefore, the first apparatus 100 further comprises a temperature detection device 40 which detects a temperature measuring point temperature Tm that is a temperature of a temperature measuring point Dm that is at least one position included in any of the high temperature heat source 10H, the low temperature heat source 10C and the thermoelectric generation module 10M, as shown in FIG. 6. As the temperature detection device 40, for example, a temperature sensor which directly measures the temperature of the temperature measuring point Dm, such as a thermocouple disposed at the temperature measuring point Dm, etc. can be adopted. However, for example, in a case where it is difficult to dispose the temperature detection device 40 at a position where the temperature measuring point temperature Tm can be directly detected, etc., the temperature detection device 40 may be disposed at a position where a temperature which has correlation with the temperature measuring point temperature Tm can be detected and the temperature measuring point temperature Tm may be calculated or presumed from the detection result. Alternatively, for example, a sensor which indirectly measures the temperature measuring point temperature Tm, such as a thermoviewer (thermography camera) using infrared ray, etc. may be adopted.

The position of the temperature measuring point Dm is not limited in particular unless the functions as the thermoelectric generation module 10M is spoiled substantially, and it can be an any position in the high temperature heat source 10H, an any position in the low temperature heat source 10C, and an any position in the thermoelectric generation module 10M, for example. However, since it is actually difficult to prepare the temperature measuring point Dm in the thermoelectric generation module 10M in many cases, it is desirable to prepare the temperature measuring point Dm at an arbitrary position in the high temperature heat source 10H or the low temperature heat source 10C. Typically, as shown in FIG. 6, the temperature measuring point Dm is prepared at an arbitrary position in the high temperature heat source 10H.

Furthermore, in the first apparatus 100, the control part Uc is configured so as to control the output adjustment device 30 to increase the output current value I or decrease the output voltage value V when the high temperature side interface temperature Tbh that is the temperature of the high temperature side interface Bh that is the interface on the high temperature heat source side of the thermoelectric conversion element 10E is judged to be higher than the predetermined upper limit temperature Tmax at least based on the temperature measuring point temperature Tm.

The above-mentioned “upper limit temperature Tmax” can be determined based on the highest high temperature side interface temperature Tbh as long as problems such as damage of the thermoelectric conversion element 10E do not occur because the high temperature side interface temperature Tbh is excessively high, for example. Since a sudden change of a temperature of a high temperature heat source such as an exhaust gas from an internal combustion engine, for example (high temperature heat source temperature Th) is assumed under actual operation of the first apparatus 100, it is desirable to determine, as the upper limit temperature Tmax, a temperature slightly lower than the above-mentioned highest value of the high temperature side interface temperature Tbh in consideration of such a fluctuation range of the temperature of the heat source. The upper limit temperature Tmax determined in this way can be stored in a storage unit such as a memory (ROM) which the control part Uc comprises as data and the CPU can refer to it as required.

Moreover, as a specific procedure for judging whether the high temperature side interface temperature Tbh is higher than the predetermined upper limit temperature Tmax or not at least based on the temperature measuring point temperature Tm, for example, various procedures based on “various detection values which have correlation with the high temperature side interface temperature Tbh” detected in the first apparatus 100 can be mentioned. Alternatively, a certain detection means to detect a value of state quantity which has correlation with the high temperature side interface temperature Tbh can be further prepared and the judgment can be carried out based on a detection result by the detection means. A specific procedure for carrying out the judgment will be explained in detail in an explanation about other embodiments of the present invention which will be mentioned later.

As mentioned above, the control part Uc is configured so as to control the output adjustment device 30 to increase the output current value I or decrease the output voltage value V when the high temperature side interface temperature Tbh is judged to be higher than the upper limit temperature Tmax at least based on the temperature measuring point temperature Tm. Specifically, the control part Uc can increase the output current value I from the thermoelectric generation module 10M or decrease the output voltage value V by inputting an instruction signal for increasing the output current value I or decreasing the output voltage value V into a DC-DC converter as the output adjustment device 30, for example.

In addition, increment ΔI of the output current value I from the thermoelectric generation module 10M and decrement ΔV of the output voltage value V from the thermoelectric generation module 10M when the high temperature side interface temperature Tbh is judged to be higher than the predetermined upper limit temperature Tmax as mentioned above may be fixed values determined beforehand. Alternatively, the increment ΔI and the decrement ΔV may be changed according to magnitude of a difference between the high temperature side interface temperature Tbh and the upper limit temperature Tmax. In this case, specifically, the increment ΔI and the decrement ΔV may become larger as the difference between the high temperature side interface temperature Tbh and the upper limit temperature Tmax becomes larger, for example.

<Operation>

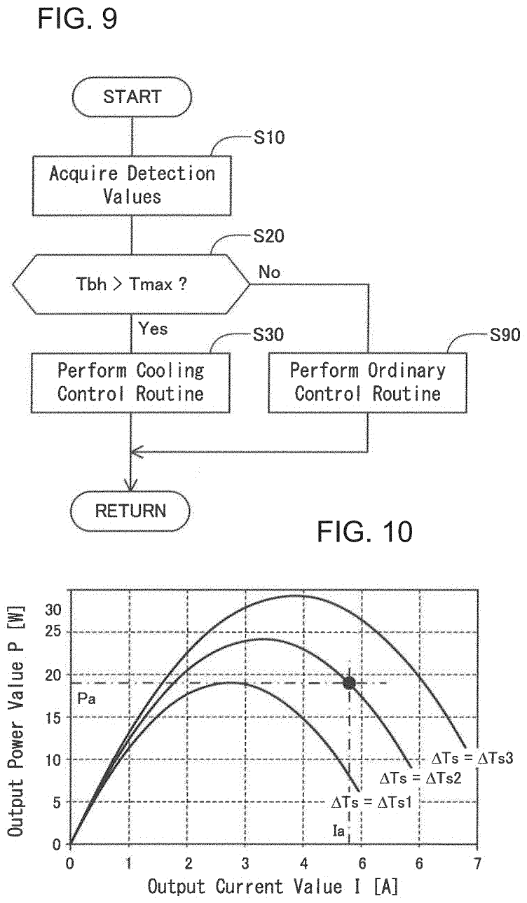

Operation of the first apparatus 100 in association with control performed by the control part Uc will be explained in detail below. FIG. 9 is a flowchart for showing an example of a control routine performed by the control part in the first apparatus 100. For example, the CPU which constitutes the control part is configured so as to perform instructions corresponding to the control routine stored in a memory (ROM) repeatedly at predetermined sufficiently short time intervals.

Once a high temperature side interface temperature control routine shown in FIG. 9 has been started, the CPU acquires a detection value required for judging whether the high temperature side interface temperature Tbh is higher than the predetermined upper limit temperature Tmax or not in step S10. Specifically, the temperature measuring point temperature Tm that is the temperature of the temperature measuring point Dm that is at least one position included in any of the high temperature heat source 10H, the low temperature heat source 10C and the thermoelectric generation module 10M is acquired from the temperature detection device 40. However, as will be explained in detail in an explanation about other embodiments of the present invention which will be mentioned later, a temperature of another position (for example, a temperature of another temperature measuring point or a temperature of the low temperature heat source 10C, etc.) may be acquired in addition to the temperature of the temperature measuring point Dm (temperature measuring point temperature Tm). Alternatively, output related values Mout that are a set of a plurality of detection values consisting of an output power value P that is magnitude of electric power output from the thermoelectric generation module 10M, an output current value I that is magnitude of electric current output from the thermoelectric generation module 10M and/or an output voltage value V that is magnitude of electric voltage output from the thermoelectric generation module 10M may be acquired.

Next, the CPU progresses to step S20, and judges whether the high temperature side interface temperature Tbh is higher than the upper limit temperature Tmax or not. Specific procedure for the judgment is properly chosen according to the detection value acquired in the above-mentioned step S10, as mentioned above. For example, as mentioned above, the high temperature side interface temperature Tbh can be determined based on the difference between the temperature of the temperature measuring point Dm (temperature measuring point temperature Tm) and the temperature of another position, a thermal conductivity λm and heat passage area Am of the region between these two positions, and the penetrating heat quantity W determined based on the distance Lm between these two positions, a thermal conductivity λbhm and heat passage area Abhm of the region between the temperature measuring point Dm and the high temperature side interface Bh, the temperature measuring point temperature Tm, and the distance Lbhm between the temperature measuring point Dm and the high temperature side interface Bh.

Alternatively, the output related values Mout that are a set of a plurality of detection values which consist of the output power value P that is magnitude of the power output from the thermoelectric generation module 10M, the output current value I that is magnitude of the electric current output from the thermoelectric generation module 10M and/or the output voltage value V that is magnitude of the electric voltage output from the thermoelectric generation module 10M can be detected to judge whether the high temperature side interface temperature Tbh is higher than the upper limit temperature Tmax or not based on the heat source temperature difference ΔTs determined from the output related values Mout. Details of a specific example of a procedure for such a judgement will be explained in detail in an explanation about other embodiments of the present invention which will be mentioned later.

When the high temperature side interface temperature Tbh is the upper limit temperature Tmax or less, the CPU judges as “No” in the above-mentioned step S20, progresses to the following step S90, and controls the output adjustment device 30 in accordance with a control routine which is to be performed at ordinary time (which may be referred to as a “ordinary control routine” hereafter) to control the output current value I and/or the output voltage value V. As a specific example of this “ordinary control routine”, an “output maximize control routine” that is a control routine for maximizing the output power value P in accordance with magnitude of the heat source temperature difference ΔTs at each occasion, such as the above-mentioned maximum power point tracking (MPPT) mentioned above, can be mentioned, for example.

On the other hand, when the high temperature side interface temperature Tbh is higher than the upper limit temperature Tmax, the CPU judges as “Yes” in the above-mentioned step S20, progresses to the following step S30. Then, the CPU performs a control routine in which the high temperature side interface temperature Tbh of the thermoelectric conversion element 10E is lowered by increasing the output current value I or decreasing the output voltage value V (which may be referred to as a “cooling control routine” hereafter). Specifically, the CPU generates an instruction signal for increasing the output current value I or decreasing the output voltage value V and transmits the instruction signal to the output adjustment device 30, for example. Then, the output adjustment device 30 (for example, a DC-DC converter, etc.) which received the instruction signal increases the output current value I from the thermoelectric generation module 10M or decreases the output voltage value V from the thermoelectric generation module 10M. As a result, as explained referring to the graph of FIG. 8, the high temperature side interface temperature Tbh of the thermoelectric conversion element 10E falls.

### Effects

As the above, the first apparatus 100 increases electric current flowing through the thermoelectric conversion element 10E by increasing the output current value I from the thermoelectric generation module 10M or decreasing the output voltage value V from the thermoelectric generation module 10M in a case where the high temperature side interface temperature Tbh is judged to be higher than the predetermined upper limit temperature Tmax at least based on the temperature measuring point temperature Tm. As a result, the thermal conductivity of the thermoelectric conversion element 10E becomes larger, the heat quantity which moves to the low temperature heat source 10C from the high temperature heat source 10H increases, and the temperature of the high temperature side interface Bh that is an interface on the high temperature heat source side of the thermoelectric conversion element 10E falls. Namely, in accordance with the first apparatus 100, when the high temperature side interface temperature Tbh is judged to be higher than the predetermined upper limit temperature Tmax, the high temperature side interface temperature Tbh of the thermoelectric conversion element 10E can be lowered quickly and effectively by increasing the output current value I from the thermoelectric generation module 10M or decreasing the output voltage value V from the thermoelectric generation module 10M. Thereby, problems such as damage of the thermoelectric conversion element 10E due to excessive rise in the high temperature side interface temperature Tbh can be avoided, for example.

In addition, in accordance with the first apparatus 100, there is no possibility to cause complication, enlargement and cost increase of a thermoelectric generation apparatus as in the case of cooling the thermoelectric conversion element 10E by heat dissipation means as mentioned above. Moreover, since heat continues to be supplied to the thermoelectric generation module 10M from the high temperature heat source 10H even when the high temperature side interface temperature Tbh of thermoelectric conversion element 10E is being lowered by increasing the output current value I or decreasing the output voltage value V as mentioned above, the high temperature side interface temperature Tbh can be quickly brought close to the upper limit temperature Tmax to quickly increase the output power value P when switching to the ordinary control routine in a case where the high temperature side interface temperature Tbh becomes sufficiently lower than the upper limit temperature Tmax,

However, the above-mentioned cooling control routine can be performed also in the first apparatus 100 which comprises a heat dissipation means for cooling the thermoelectric conversion element 10E. Since a certain length of time period is required for cooling the thermoelectric conversion element 10E by heat dissipation, the interface on the high temperature heat source side of the thermoelectric conversion element 10E (high temperature side interface Bh) can be cooled quickly by performing the cooling control routine in a time period until cooling efficiency of the thermoelectric conversion element 10E by heat dissipation means fully increases.

Namely, in accordance with the first apparatus 100, since the high temperature side interface temperature Tbh of the thermoelectric conversion element 10E can be lowered quickly and effectively, the thermoelectric generation apparatus can be worked at high generating efficiency while preventing damage of the thermoelectric conversion element 10E.

### Second Embodiment

Hereafter, a thermoelectric generation apparatus according to a second embodiment of the present invention (which may be referred to as a “second apparatus” hereafter) will be explained.

<Configuration>

As mentioned above, it is possible to judge whether the high temperature side interface temperature Tbh is higher than the predetermined upper limit temperature Tmax or not at least based on the temperature of the temperature measuring point Dm (temperature measuring point temperature Tm) and a temperature of another position. Therefore, the second apparatus has the same configuration as that of the above-mentioned first apparatus 100 except for points described in the following (a) to (d).

(a) The temperature detection device 40 is configured so as to respectively detect a first temperature measuring point temperature Tm1 and second temperature measuring point temperature Tm2 that are temperatures of a first temperature measuring point Dm1 and second temperature measuring point Dm2 that are two of the temperature measuring points located a predetermined interval apart from each other in a heat flow direction that is a flow direction of heat moving to the low temperature heat source 10C from the high temperature heat source 10H via the thermoelectric generation module 10M.

(b) The control part Uc is configured so as to determine penetrating heat quantity W that is quantity of heat moving to the low temperature heat source 10C from the high temperature heat source 10H via the thermoelectric generation module 10M, based on a difference between the first temperature measuring point temperature Tm1 and the second temperature measuring point temperature Tm2, a thermal conductivity λm12 and heat passage area λm12 of a region between the first temperature measuring point Dm1 and the second temperature measuring point Dm2 in the heat flow direction, and a distance Lm12 between the first temperature measuring point Dm1 and the second temperature measuring point Dm2 in the heat flow direction.

(c) The control part Uc is configured so as to determine the high temperature side interface temperature Tbh, based on the first temperature measuring point temperature Tm1 and/or the second temperature measuring point temperature Tm2, thermal conductivities (λbhm1 and/or λbhm2) and heat passage areas (Abhm1 and/or Abhm2) of regions to the first temperature measuring point Dm1 and/or the second temperature measuring point Dm2 from the high temperature side interface Bh in the heat flow direction, the penetrating heat quantity W and distances (Lbhm1 and/or Lbhm2) to the first temperature measuring point Dm1 and/or the second temperature measuring point Dm2 from the high temperature side interface Bh in the heat flow direction.

(d) The control part Uc is configured so as to judge whether the high temperature side interface temperature Tbh is higher than the upper limit temperature Tmax or not.

As described in the above-mentioned (a), the temperature detection device 40 which the second apparatus comprises is configured so as to detect the first temperature measuring point temperature Tm1 and second temperature measuring point temperature Tm2 that are the temperatures of the first temperature measuring point Dm1 and second temperature measuring point Dm2 respectively. As mentioned above, the first temperature measuring point temperature Tm1 and the second temperature measuring point temperature Tm2 are the temperatures of the first temperature measuring point Dm1 and second temperature measuring point Dm2 that are two temperature measuring points located a predetermined interval apart from each other in the heat flow direction that is a flow direction of heat moving to the low temperature heat source 10C from the high temperature heat source 10H via the thermoelectric generation module 10M, respectively.

Specific positions of the first temperature measuring point Dm1 and the second temperature measuring point Dm2 are not limited in particular unless functions as an thermoelectric generation module is spoiled substantially, and they can be any positions in the high temperature heat source 10H, any positions in the low temperature heat source 10C and the any positions in the thermoelectric generation module 10M, for example. However, since it is actually difficult to prepare the temperature measuring point Dm in the thermoelectric generation module 10M in many cases, it is desirable to prepare the first temperature measuring point Dm1 and the second temperature measuring point Dm2 at an arbitrary position in the high temperature heat source 10H or the low temperature heat source 10C. Typically, the first temperature measuring point Dm1 and the second temperature measuring point Dm2 are prepared at two arbitrary positions in the low temperature heat source 10C.

As described in the above-mentioned (b), the control part Uc is configured so as to determine the penetrating heat quantity W that is quantity of heat moving to the low temperature heat source 10C from the high temperature heat source 10H via the thermoelectric generation module 10M, based on a difference ΔTm12 between the first temperature measuring point temperature Tm1 and the second temperature measuring point temperature Tm2 (ΔTm12=Tm1−Tm2), the thermal conductivity λm12 and heat passage area Am12 of a region between the first temperature measuring point Dm1 and the second temperature measuring point Dm2 in the heat flow direction, and the distance Lm12 between the first temperature measuring point Dm1 and the second temperature measuring point Dm2 in the heat flow direction (namely, the above-mentioned “predetermined interval”). Specifically, the penetrating heat quantity W can be calculated by a formula (1) shown below. In the formula (1), the first temperature measuring point temperature Tm1 and the second temperature measuring point temperature Tm2 can be acquired from the temperature detection device 40, and the thermal conductivity λm12 and heat passage area λm12 and the distance Lm12 are known values determined in accordance with a design specification of the second apparatus.

$$\begin{matrix}W = \vert \frac{λ m 12 \times ( Tm 1 - Tm 2 ) \times Am 12}{Lm 12} \vert \\ = \vert \frac{λ m 12 \times Δ Tm 12 \times Am 12}{Lm 12} \vert\end{matrix} \qquad ( 1 )$$

Furthermore, as described in the above-mentioned (c), the control part Uc is configured so as to determine the high temperature side interface temperature Tbh, based on the first temperature measuring point temperature Tm1 and/or the second temperature measuring point temperature Tm2, thermal conductivities (λbhm1 and/or λbhm2) and heat passage areas (λbhm1 and/or λbhm2) of regions to the first temperature measuring point Dm1 and/or the second temperature measuring point Dm2 from the high temperature side interface Bh in the heat flow direction, the penetrating heat quantity W and distances (Lbhm1 and/or Lbhm2) to the first temperature measuring point Dm1 and/or the second temperature measuring point Dm2 from the high temperature side interface Bh in the heat flow direction.

Specifically, the high temperature side interface temperature Tbh can be calculated by the formula (2) and/or formula (3) shown below. In the formula (2) and a formula (3), the first temperature measuring point temperature Tm1 and the second temperature measuring point temperature Tm2 can be acquired from the temperature detection device 40, the thermal conductivities λbhm1 and λbhm2, the heat passage areas λbhm1 and λbhm2, and the distances Lbhm1 and Lbhm2 are known values determined in accordance with the design specification of the second apparatus.

$$\begin{matrix}Tbh = Tm 1 + \frac{W \times Lbhm 1}{λ bhm 1 \times Abhm 1} ( Tbh > Tm 1 ) \\ Tbh = Tm 1 - \frac{W \times Lbhm 1}{λ bhm 1 \times Abhm 1} ( Tbh < Tm 1 ) & ( 2 ) \\ Tbh = Tm 2 + \frac{W \times Lbhm 2}{λ bhm 2 \times Abhm 2} ( Tbh > Tm 2 ) \\ Tbh = Tm 2 - \frac{W \times Lbhm 2}{λ bhm 2 \times Abhm 2} ( Tbh < Tm 2 ) & ( 3 )\end{matrix}$$

As shown in the formula (2), when the first temperature measuring point Dm1 is located on the low temperature heat source side rather than the high temperature side interface Bh (namely, Tbh>Tm1), the sign before the second term of the right side in the formula (2) becomes plus (+). On the other hand, when the first temperature measuring point Dm1 is located on the high temperature heat source side rather than the high temperature side interface Bh (namely, Tbh<Tm1), the sign before the second term of the right side in the formula (2) becomes minus (−). Moreover, as shown in the formula (3), when the second temperature measuring point Dm2 is located on the low temperature heat source side rather than the high temperature side interface Bh (namely, Tbh>Tm2), the sign before the second term of the right side in the formula (3) become plus (+). On the other hand, when the second temperature measuring point Dm2 is located on the high temperature heat source side rather than the high temperature side interface Bh (namely, Tbh<Tm2), the sign before the second term of the right side in the formula (3) become minus (−).

In addition, the high temperature side interface temperature Tbh may be calculated using only either one of the formula (2) and the formula (3) or an average value of the high temperature side interface temperature Tbh calculated by the formula (2) and the high temperature side interface temperature Tbh calculated by the formula (3) may be adopted as the high temperature side interface temperature Tbh.

By the way, as mentioned above, in the present invention apparatus including the first apparatus and the second apparatus, heat flows to the low temperature heat source 10C from the high temperature heat source 10H via the thermoelectric generation module 10M along one thermal circuit in which the high temperature heat source 10H and the thermoelectric generation module 10M and the low temperature heat source 10C are connected in series. Therefore, at any positions on the thermal circuit in the present invention apparatus, the penetrating heat quantity W has the same magnitude. Moreover, heat moves to an interface between the low temperature heat source 10C and the thermoelectric generation module 10M from an interface of the high temperature heat source 10H and the thermoelectric generation module 10M. Furthermore, generally, the present invention apparatus is constituted by a tabular thermoelectric generation module 10M interposed between the high temperature heat source 10H and the low temperature heat source 10C. Therefore, in this case, the heat passage area A can be considered to have the same magnitude at any positions on the thermal circuit in the present invention apparatus. Namely, all the heat passage areas including the heat passage area λm12, λbhm1 and λbhm2 can be considered to have the same magnitude at any positions on the thermal circuit in the present invention apparatus.

In addition, as indicated in the above-mentioned (d), the control part Uc is configured so as to judge whether the high temperature side interface temperature Tbh determined as described in the above-mentioned (c) is higher than the upper limit temperature Tmax or not.

### Effects

As the above, the second apparatus increases electric current which flows through the thermoelectric conversion element 10E by increasing the output current value I from the thermoelectric generation module 10M or decreasing the output voltage value V from the thermoelectric generation module 10M when the high temperature side interface temperature Tbh determined based on the first temperature measuring point temperature Tm1 and the second temperature measuring point temperature Tm2 is judged to be higher than the predetermined upper limit temperature Tmax. Therefore, the same effects as those of the above-mentioned first apparatus 100 can be attained more certainly. Namely, in accordance with the second apparatus, since the high temperature side interface temperature Tbh of the thermoelectric conversion element 10E can be lowered more quickly and effectively, the thermoelectric generation apparatus can be worked at high generating efficiency while preventing damage of the thermoelectric conversion element 10E.

### Third Embodiment

Hereafter, a thermoelectric generation apparatus according to a third embodiment of the present invention (which may be referred to as a “third apparatus” hereafter) will be explained.

<Configuration>

As mentioned above, there is a high possibility that the high temperature heat source temperature Th may change according to an operational state of a supply source of the high temperature heat source 10H (for example, an internal combustion engine, etc.), etc., for example. On the other hand, the low temperature heat source temperature Tc may be maintained at a constant temperature in accordance with a design specification of the thermoelectric generation apparatus, etc., for example. In this case, the high temperature side interface temperature Tbh can be determined based on a difference between a temperature of the temperature measuring point Dm (temperature measuring point temperature Tm) and a temperature at an arbitrary position (where a constant temperature corresponding to the low temperature heat source temperature Tc is maintained) in the low temperature heat source 10C.

Then, the third apparatus has the same configuration as that of the above-mentioned first apparatus except for points described in the following (e) to (g) and (d). In addition, the following (d) is the same as (d) in the above-mentioned second apparatus.

(e) A low temperature side temperature measuring point temperature Tmc that is a temperature of a low temperature side temperature measuring point Dmc that is at least one position included in the low temperature heat source 10C is maintained at a constant temperature.

(f) The control part Uc is configured so as to determine penetrating heat quantity W that is quantity of heat moving to the low temperature heat source 10C from the high temperature heat source 10H via the thermoelectric generation module 10M, based on a difference between the temperature measuring point temperature Tm and the low temperature side temperature measuring point temperature Tmc, a thermal conductivity λmmc and heat passage area λmmc of a region between the temperature measuring point Dm and the low temperature side temperature measuring point Dmc in a heat flow direction that is a flow direction of heat moving to the low temperature heat source 10C from the high temperature heat source 10H via the thermoelectric generation module 10M, and a distance Lmmc between the temperature measuring point Dm and the low temperature side temperature measuring point Dmc in the heat flow direction.

(g) The control part Uc is configured so as to determine the high temperature side interface temperature Tbh, based on the temperature measuring point temperature Tm, thermal conductivities (λbhm and/or λbhmc) and heat passage areas (Abhm and/or Abhmc) of regions to the temperature measuring point Dm and/or the low temperature side temperature measuring point Dmc from the high temperature side interface Bh in the heat flow direction, the penetrating heat quantity W and distances (Lbhm and/or Lbhmc) to the temperature measuring point Dm and/or the low temperature side temperature measuring point Dmc from the high temperature side interface Bh in the heat flow direction.

(d) The control part Uc is configured so as to judge whether the high temperature side interface temperature Tbh is higher than the upper limit temperature Tmax or not.

The third apparatus is a thermoelectric generation apparatus in which the low temperature side temperature measuring point temperature Tmc that is the temperature of the low temperature side temperature measuring point Dmc that is at least one position included in the low temperature heat source 10C is maintained at a constant temperature, as described in the above-mentioned (e). The specific location of the low temperature side temperature measuring point Dmc is not limited in particular unless functions as a thermoelectric generation module is spoiled substantially and it can be any position in the low temperature heat source 10C, for example.

Since the low temperature heat source temperature Tc is maintained at a constant temperature in the third apparatus as mentioned above, the low temperature side temperature measuring point temperature Tmc is maintained at a constant temperature corresponding to the low temperature heat source temperature Tc. Therefore, in the third apparatus, the penetrating heat quantity W can be determined based on the temperature measuring point temperature Tm and the low temperature side temperature measuring point temperature Tmc, etc., without actually detecting the low temperature side temperature measuring point temperature Tmc, and it can be judged whether the high temperature side interface temperature Tbh is higher than the upper limit temperature Tmax or not. For that reason, since no configuration needs to be added for detecting the low temperature side temperature measuring point temperature Tmc, problems such as complication, enlargement and cost increase of the third apparatus can be avoided, for example.

In addition, when the temperature detection device 40 which the third apparatus comprises for the purpose of maintaining the low temperature heat source temperature Tc at a constant temperature, etc., for example, is configured so as to detect the low temperature heat source temperature Tc and the temperature measuring point Dc where the low temperature heat source temperature Tc is detected is included in a thermal circuit through which heat flows to the low temperature heat source 10C from the high temperature heat source 10H via the thermoelectric generation module 10M, the low temperature heat source temperature Tc can be adopted as the low temperature side temperature measuring point temperature Tmc and the temperature measuring point Dc can be adopted as the low temperature side temperature measuring point Dmc, respectively. Since no configuration for detecting the low temperature side temperature measuring point temperature Tmc needs to be added also in this case, problems such as complication, enlargement and cost increase of the third apparatus can be avoided, for example.

As described in the above-mentioned (f), the control part Uc is configured so as to determine the penetrating heat quantity W that is quantity of the heat moving to the low temperature heat source 10C from the high temperature heat source 10H via the thermoelectric generation module 10M, based on the difference ΔTmmc between the temperature measuring point temperature Tm and the low temperature side temperature measuring point temperature Tmc (ΔTmmc=Tm−Tmc), a thermal conductivity λmmc and heat passage area λmmc of a region between the temperature measuring point Dm and the low temperature side temperature measuring point Dmc in the heat flow direction that is the flow direction of the heat moving to the low temperature heat source 10C from the high temperature heat source 10H via the thermoelectric generation module 10M, and the distance Lmmc between the temperature measuring point Dm and the low temperature side temperature measuring point Dmc in the heat flow direction. Specifically, the penetrating heat quantity W can be calculated by the formula (4) shown below. In the formula (4), the temperature measuring point temperature Tm can be acquired from the temperature detection device 40, and the low temperature side temperature measuring point temperature Tmc, the thermal conductivity λmmc, the heat passage area Ammc and the distance Lmmc are known values determined in accordance with a design specification of the third apparatus.

$$\begin{matrix}W = \vert \frac{λ mmc \times ( Tm - Tmc ) \times Ammc}{Lmmc} \vert \\ = \vert \frac{λ mmc \times Δ Tmmc \times Ammc}{Lmmc} \vert\end{matrix} \qquad ( 4 )$$

Furthermore, as described in the above-mentioned (g), the control part Uc is configured so as to determine the high temperature side interface temperature Tbh, based on the temperature measuring point temperature Tm, thermal conductivities (λbhm and/or λbhmc) and heat passage areas (Abhm and/or Abhmc) of regions to the temperature measuring point Dm and/or the low temperature side temperature measuring point Dmc from the high temperature side interface Bh in the heat flow direction, the penetrating heat quantity W and distances (Lbhm and/or Lbhmc) to the temperature measuring point Dm and/or the low temperature side temperature measuring point Dmc from the high temperature side interface Bh in the heat flow direction. Specifically, the high temperature side interface temperature Tbh can be calculated by a formula (5) and/or a formula (6) shown below. In the formula (5) and the formula (6), the temperature measuring point temperature Tm can be acquired from the temperature detection device 40, and the low temperature side temperature measuring point temperature Tmc, the thermal conductivities λbhm and λbhmc, the heat passage areas Abhm and Abhmc and the distances Lbhm and Lbhmc are known values determined in accordance with the design specification of the third apparatus.

$$\begin{matrix}Tbh = Tm + \frac{W \times Lbhm}{λ bhm \times Abhm} ( Tbh > Tm ) \\ Tbh = Tm - \frac{W \times Lbhm}{λ bhm \times Abhm} ( Tbh < Tm ) & ( 5 ) \\ Tbh = Tmc + \frac{W \times Lbhmc}{λ bhmc \times Abhmc} ( Tbh > Tmc ) \\ Tbh = Tmc - \frac{W \times Lbhmc}{λ bhmc \times Abhmc} ( Tbh < Tmc ) & ( 6 )\end{matrix}$$

As shown in the formula (5), when the high temperature side interface Bh is located on the high temperature heat source side rather than the temperature measuring point Dm (namely, Tbh>Tm), the sign before the second term of the right side in the formula (5) becomes plus (+). On the other hand, when the high temperature side interface Bh is located on the low temperature heat source side rather than the temperature measuring point Dm (namely, Tbh<Tm), the sign before the second term of the right side in the formula (5) becomes minus (−). Moreover, as shown in the formula (6), when the high temperature side interface Bh is located on the high temperature heat source side rather than the low temperature side temperature measuring point Dmc (namely, Tbh>Tmc), the sign before the second term of the right side in the formula (6) becomes plus (+). On the other hand, when the high temperature side interface Bh is located on the low temperature heat source side rather than the low temperature side temperature measuring point Dmc (namely, Tbh<Tmc), the sign before the second term of the right side in the formula (6) becomes minus (−).

In addition, the high temperature side interface temperature Tbh may be calculated using only either one of the formula (5) and the formula (6) or an average value of the high temperature side interface temperature Tbh calculated by the formula (5) and the high temperature side interface temperature Tbh calculated by the formula (6) may be adopted as the high temperature side interface temperature Tbh.

By the way, as mentioned above, the magnitude of the penetrating heat quantity W can be considered to be the same at any positions on the thermal circuit in the present invention apparatus including the first apparatus to the third apparatus. Moreover, the magnitude of the heat passage area A can be considered to be the same at any positions on the thermal circuit in the present invention apparatus. Namely, all the heat passage areas including the heat passage areas Ammc, Abhm and Abhmc can be considered to have the same magnitudes at any positions on the thermal circuit in the present invention apparatus.

In addition, as described in the above-mentioned (d), the control part Uc is configured so as to judge whether the high temperature side interface temperature Tbh determined as described in the above-mentioned (g) is higher than the upper limit temperature Tmax or not.

### Effects

As the above, the third apparatus increase the electric current which flows through the thermoelectric conversion element 10E by increasing the output current value I from the thermoelectric generation module 10M or decreasing the output voltage value V from the thermoelectric generation module 10M when the high temperature side interface temperature Tbh determined based on the temperature measuring point temperature Tm and the low temperature side temperature measuring point temperature Tmc is judged to be higher than the predetermined upper limit temperature Tmax Therefore, the same effects as those of the above-mentioned first apparatus can be attained more certainly. Namely, in accordance with the third apparatus, since the high temperature side interface temperature Tbh of the thermoelectric conversion element 10E can be lowered more quickly and effectively, the thermoelectric generation apparatus can be worked at high generating efficiency while preventing damage of the thermoelectric conversion element 10E.

### Fourth Embodiment

Hereafter, a thermoelectric generation apparatus according to a fourth embodiment of the present invention (which may be referred to as a “fourth apparatus” hereafter) will be explained.

<Configuration>

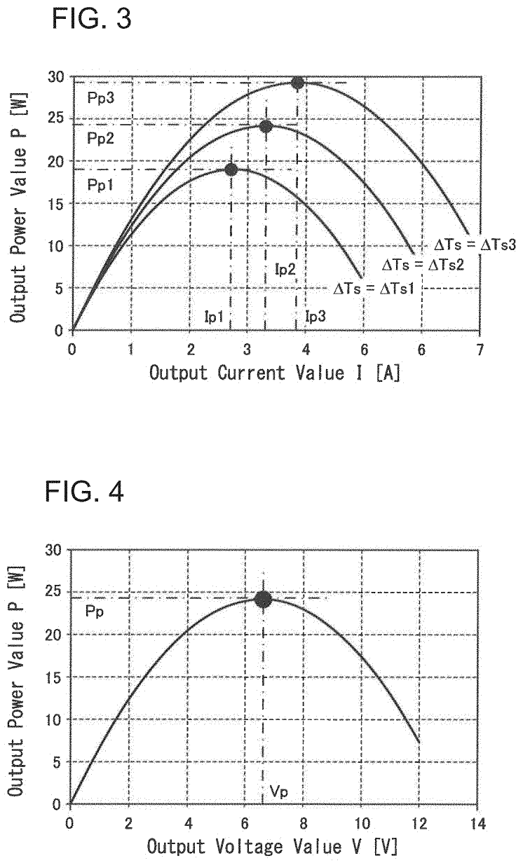

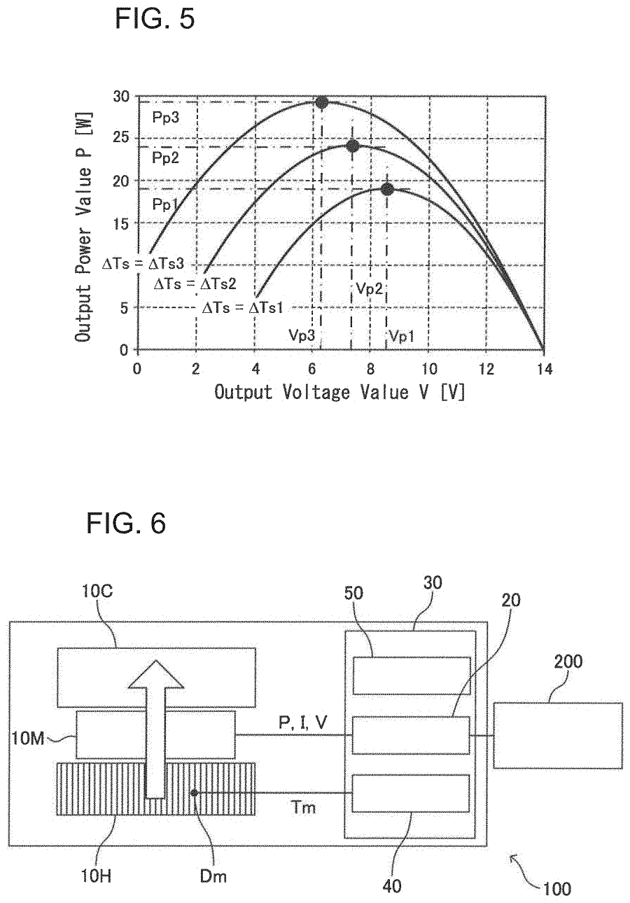

As explained referring to the graphs of FIG. 3 and FIG. 5, the relation between the output current value I and the output power value P and the relation between the output voltage value V and the output power value P from the thermoelectric generation module 10M change in accordance with the magnitude of the heat source temperature difference ΔTs, respectively. Moreover, the specific output current value Ip at which the maximum output power value Pp is acquired and the magnitude of the maximum output power value Pp acquired at the specific output current value Ip also change in accordance with the magnitude of the heat source temperature difference ΔTs. Similarly, the specific output voltage value Vp at which the maximum output power value Pp is acquired and the magnitude of the maximum output power value Pp acquired at the specific output voltage value Vp also change in accordance with the magnitude of heat source temperature difference ΔTs.

Therefore, by previously obtaining a relation between the heat source temperature difference ΔTs and the output power value P and the output current value I and/or the output voltage value V in the thermoelectric generation module 10M, through a pre-experimentation using the thermoelectric generation module 10M, etc., for example, the heat source temperature difference ΔTs can be determined, based on the relation, from the output power value P and the output current value I and/or the output voltage value V under operation of the thermoelectric generation module 10M. The penetrating heat quantity W can be determined based on the heat source temperature difference ΔTs determined in this way and the thermal conductivity λs of the corresponding region in the thermoelectric generation module 10M, etc. After the penetrating heat quantity W has been determined in this way, the high temperature side interface temperature Tbh can be determined in accordance with the same procedure as that in the above-mentioned third apparatus, for example.

Then, the fourth apparatus has the same configuration as that of the above-mentioned first apparatus except for points described in the following (h) to (l) and (d). In addition, the following (d) is the same as (d) in the above-mentioned second apparatus and third apparatus.

(h) The fourth apparatus further comprises an output detection device 20 which detects output related values Mout that are a set of a plurality of detection values consisting of an output power value P that is magnitude of electric power output from the thermoelectric generation module 10M, an output current value I that is magnitude of electric current output from the thermoelectric generation module 10M and/or an output voltage value V that is magnitude of electric voltage output from the thermoelectric generation module 10M.

(i) The control part Uc has previously stored first characteristic data that is data representing a relation between the heat source temperature difference ΔTs and the output related values Mout.

(j) The control part Uc is configured so as to determine the heat source temperature difference ΔTs based on the first characteristic data from the output related values Mout detected by the output detection device 20.

(k) The control part Uc is configured so as to determine the penetrating heat quantity W, based on the heat source temperature difference ΔTs, a thermal conductivity λs and heat passage area As of a region where the heat source temperature difference ΔTs is produced, and a length Ls of the region where the heat source temperature difference ΔTs is produced in a heat flow direction that is a flow direction of heat moving to the low temperature heat source 10C from the high temperature heat source 10H via the thermoelectric generation module 10M.

(l) The control part Uc is configured so as to determine the high temperature side interface temperature Tbh, based on the temperature measuring point temperature Tm, a thermal conductivity λbhm and heat passage area λbhm of a region between the temperature measuring point Dm and the high temperature side interface Bh in the heat flow direction, the penetrating heat quantity W and a distance Lbhm between the temperature measuring point Dm and the high temperature side interface Bh in the heat flow direction.

(d) The control part Uc is configured so as to judge whether the high temperature side interface temperature Tbh is higher than the upper limit temperature Tmax or not.

The fourth apparatus further comprises the output detection device 20 which detects the output related values Mout, as described in the above-mentioned (h). The output related values Mout are a set of a plurality of detection values consisting of the output power value P that is magnitude of electric power output from the thermoelectric generation module 10M, the output current value I that is magnitude of electric current output from the thermoelectric generation module 10M and/or the output voltage value V that is magnitude of electric voltage output from the thermoelectric generation module 10M. The output related values Mout may be a set of two detection values consisting of the output power value P and the output current value I, may be a set of two detection values consisting of the output power value P and the output voltage value V, or may be a set of three detection values consisting of the output power value P, the output current value I and the output voltage value V.

A configuration of the output detection device 20 is not limited in particular, as long as it is possible to detect the output power value P, the output current value I and/or the output voltage value V. As a specific example of such an output detection device 20, an electric current sensor and an electric voltage sensor, etc. can be mentioned, for example. However, an electric current sensor and an electric voltage sensor, etc. which another apparatuses to which electric power output from the thermoelectric generation module 10M is supplied, such as the above-mentioned output adjustment device 30, may be used as the output detection device 20, for example.

The control part Uc has previously stored the first characteristic data that is data representing the relation between the heat source temperature difference ΔTs and the output related values Mout, as described in the above-mentioned (i). The first characteristic data can be acquired by previously obtaining a relation between the heat source temperature difference ΔTs, the output power value P and the output current value I and/or the output voltage value V in the thermoelectric generation module 10M, through a pre-experimentation using the fourth apparatus, etc. Moreover, the first characteristic data can be stored in a storage unit such as a memory (ROM) which the control part comprises as electronic data representing the relation.

The first characteristic data is not limited in particular, as long as it is data representing the relation between the heat source temperature difference ΔTs and the output related values Mout. For example, the first characteristic data may be a plurality of data tables or data maps representing the relation between the output power value P and the output current value I or the output voltage value V for each of various heat source temperature differences ΔTs's. Alternatively, the first characteristic data may be one data table or one data map representing the relation between the heat source temperature difference ΔTs and the output power value P and the output current value I or the output voltage value V. Furthermore, the first characteristic data may be a function representing a relation between the output power value P and the output current value I or the output voltage value V for each of various heat source temperature differences ΔTs's. Alternatively, the first characteristic data may be one function representing the relation between the heat source temperature difference ΔTs, the output power P and the output current value I or the output voltage value V.

And, based on the output related values Mout detected by the output detection device 20 and the first characteristic data, it can be judged whether the high temperature side interface temperature Tbh is higher than the upper limit temperature Tmax or not, as follows.

As described in the above-mentioned (j), the control part Uc is configured so as to determine the heat source temperature difference ΔTs at that time point based on the first characteristic data from the output related values Mout detected by the output detection device 20. For example, a case where the output detection device 20 detects, as the output related values Mout, an output power value Pa and an output current value Ia output from the thermoelectric generation module 10M at a certain time point is supposed. Moreover, it is supposed that the first characteristic data is a plurality of data tables or data maps representing a relation between the output power value P and the output current value I for each of various heat source temperature difference ΔTs's. In this case, the first characteristic data can be expressed by a graph shown in FIG. 10, for example. Respective curves in the graph of FIG. 10 represent relations between the output power value P and the output current value I at different heat source temperature differences ΔTs's (=ΔTs1, ΔTs2, ΔTs3 . . . ). As shown by a black round mark in FIG. 10, only the curve in a case where the heat source temperature difference ΔTs is ΔTs2 can match the combination of the output power value Pa and the output current value Ia detected by the output detection device 20. Thus, it can be determined that the heat source temperature difference ΔTs is equal to ΔTs2 at this time point.

Furthermore, as described in the above-mentioned (k), the control part Uc is configured so as to determine the penetrating heat quantity W, based on the heat source temperature difference ΔTs, a thermal conductivity λs and heat passage area As of the region where the heat source temperature difference ΔTs is produced, and the length Ls of the region where the heat source temperature difference ΔTs is produced in the heat flow direction that is the flow direction of the heat moving to the low temperature heat source 10C from the high temperature heat source 10H via the thermoelectric generation module 10M. For example, when the heat source temperature difference ΔTs is defined as a difference between a high temperature heat source temperature Th that is a temperature detected in a temperature measuring point Dh in the high temperature heat source 10H and a low temperature heat source temperature Tc that is a temperature detected in a temperature measuring point Dc in the low temperature heat source 10C, this “region where the heat source temperature difference ΔTs is produced” means a region of the fourth apparatus (the high temperature heat source 10H, the thermoelectric generation module 10M, and the low temperature heat source 10C) located between the temperature measuring point Dh and the temperature measuring point Dc in the heat flow direction.

The penetrating heat quantity W can be calculated by a formula (7) shown below, for example. In the formula (7), the heat source temperature difference ΔTs can be determined as described in the above-mentioned (j), and the thermal conductivity λs, the heat passage area As and the distance (length) Ls are known values determined in accordance with a design specification of the fourth apparatus.

$$W = \vert \frac{λ s \times Δ Ts \times As}{Ls} \vert \qquad ( 7 )$$

Furthermore, as described in the above-mentioned (I), the control part Uc is configured so as to determine the high temperature side interface temperature Tbh based on the temperature measuring point temperature Tm, the thermal conductivity λbhm and heat passage area Abhm of the region between the temperature measuring point Dm and the high temperature side interface Bh in the heat flow direction, the penetrating heat quantity W and the distance Lbhm between the temperature measuring point Dm and the high temperature side interface Bh in the heat flow direction. Specifically, the high temperature side interface temperature Tbh can be calculated by a formula (8) shown below. In the formula (8), the temperature measuring point temperature Tm can be acquired from the temperature detection device 40, and the thermal conductivity λbhm, the heat passage area Abhm and the distance Lbhm are known values determined in accordance with the design specification of the fourth apparatus.

$$Tbh = Tm + \frac{W \times Lbhm}{λ bhm \times Abhm} ( Tbh > Tm ) \\ Tbh = Tm - \frac{W \times Lbhm}{λ bhm \times Abhm} ( Tbh < Tm ) \qquad ( 8 )$$

As shown in the formula (8), when the temperature measuring point Dm is located on the low temperature heat source side rather than the high temperature side interface Bh (namely, Tbh>Tm), the sign before the second term of the right side in the formula (8) becomes plus (+). On the other hand, when the temperature measuring point Dm is located on the high temperature heat source side rather than the high temperature side interface Bh (namely, Tbh<Tm), the sign before the second term of the right side in the formula (8) becomes minus (−).

By the way, as mentioned above, the penetrating heat quantity W has the same magnitude at any positions on the thermal circuit in the present invention apparatus including the first apparatus to the fourth apparatus. Moreover, it can be considered that the heat passage area A has the same magnitude at any positions in the present invention apparatus. Namely, it can be considered that all the heat passage areas including the heat passage areas As and λbhm have the same magnitude at any positions on the thermal circuit in the present invention apparatus.

In addition, as described in the above-mentioned (d), the control part Uc is configured so as to judge whether the high temperature side interface temperature Tbh determined as described in the above-mentioned (l) is higher than the upper limit temperature Tmax or not.

### Effects

As the above, the fourth apparatus increases the electric current which flows through the thermoelectric conversion element 10E by increasing the output current value I from the thermoelectric generation module 10M or decreasing the output voltage value V from the thermoelectric generation module 10M, when the high temperature side interface temperature Tbh determined based on the output related values Mout, the first characteristic data and the temperature measuring point temperature Tm is judged to be higher than the predetermined upper limit temperature Tmax. Therefore, the same effects as those of the above-mentioned first apparatus can be attained more certainly. Namely, in accordance with the fourth apparatus, since the high temperature side interface temperature Tbh of the thermoelectric conversion element 10E can be lowered more quickly and effectively, the thermoelectric generation apparatus can be worked at high generating efficiency while preventing damage of the thermoelectric conversion element 10E.

### Fifth Embodiment

Hereafter, a thermoelectric generation apparatus according to a fifth embodiment of the present invention (which may be referred to as a “fifth apparatus” hereafter) will be explained.

<Configuration>

As mentioned above, in the thermoelectric generation apparatus according to the present inventions including the first apparatus (present invention apparatus), the control part is configured so as to increase the output current value I or decrease the output voltage value V by controlling the output adjustment device 30 when the high temperature side interface temperature Tbh is judged to be higher than the predetermined upper limit temperature Tmax at least based on the temperature measuring point temperature Tm. In the above-mentioned second apparatus to the fourth apparatus among these present invention apparatuses, the high temperature side interface temperature Tbh is determined at least based on the temperature measuring point temperature Tm, and the above-mentioned judgement is carried out. However, in order to carry out the above-mentioned judgement, it is not always necessary to determine the high temperature side interface temperature Tbh itself.

Then, the fifth apparatus calculates upper limit penetrating heat quantity Wmax that is the penetrating heat quantity when the high temperature side interface temperature Tbh is equal to the upper limit temperature Tmax, determines the penetrating heat quantity W at that time point similarly to the above-mentioned fourth apparatus, and judges whether the high temperature side interface temperature Tbh is higher than the upper limit temperature Tmax or not by comparing them (the upper limit penetrating heat quantity Wmax and the penetrating heat quantity W).

Specifically, the fifth apparatus has the same configuration as that of the above-mentioned first apparatus except for points described in the following (h) to (k), (m) and (n). In addition, the following (h) to (k) are the same as the (h) to (k) in the above-mentioned fourth apparatus.

(h) The fifth apparatus further comprises an output detection device 20 which detects output related values Mout that are a set of a plurality of detection values consisting of an output power value P that is magnitude of electric power output from the thermoelectric generation module 10M, an output current value I that is magnitude of electric current output from the thermoelectric generation module 10M and/or an output voltage value V that is magnitude of electric voltage output from the thermoelectric generation module 10M.

(i) The control part Uc has previously stored first characteristic data that is data representing a relation between the heat source temperature difference ΔTs and the output related values Mout.

(j) The control part Uc is configured so as to determine the heat source temperature difference ΔTs based on the first characteristic data from the output related values detected by the output detection device 20.

(k) The control part Uc is configured so as to determine the penetrating heat quantity W, based on the heat source temperature difference ΔTs, a thermal conductivityAs and heat passage area As of a region where the heat source temperature difference ΔTs is produced, and a length Ls of the region where the heat source temperature difference ΔTs is produced in a heat flow direction that is a flow direction of heat moving to the low temperature heat source 10C from the high temperature heat source 10H via the thermoelectric generation module 10M.

(m) The control part Uc is configured so as to determine the upper limit penetrating heat quantity Wmax that is magnitude of quantity of heat which moves to the high temperature side interface Bh from the temperature measuring point Dm when the high temperature side interface temperature Tbh is equal to the upper limit temperature Tmax, based on a difference between the temperature measuring point temperature Tm and the high temperature side interface temperature Tbh when the high temperature side interface temperature Tbh is equal to the upper limit temperature Tmax, a thermal conductivity λbhm and heat passage area λbhm of a region between the temperature measuring point Dm and the high temperature side interface Bh in the heat flow direction and a distance Lbhm between the temperature measuring point Dm and the high temperature side interface Bh in the heat flow direction.

(n) The control part Uc is configured so as to judge that the high temperature side interface temperature Tbh is higher than the upper limit temperature Tmax when the penetrating heat quantity W is smaller than the upper limit penetrating heat quantity Wmax in a case where the temperature measuring point Dm is closer to the high temperature heat source 10H than the high temperature side interface Bh and judge that the high temperature side interface temperature Tbh is higher than the upper limit temperature Tmax when the penetrating heat quantity W is larger than the upper limit penetrating heat quantity Wmax in a case where the temperature measuring point Dm is closer to the low temperature heat source 10C than the high temperature side interface Bh.

Although the explanation here anew is omitted as for the above-mentioned (h) to (k) since they are the same as the (h) or (k) in the fourth apparatus as mentioned above, the penetrating heat quantity W can be calculated by determining the heat source temperature difference ΔTs as described in the above-mentioned ( ) and processing as described in the above-mentioned (k).

Furthermore, as described in the above-mentioned (m), the control part Uc is configured so as to determine the upper limit penetrating heat quantity Wmax. The upper limit penetrating heat quantity Wmax is magnitude of quantity of heat which moves to the high temperature side interface Bh from the temperature measuring point Dm when the high temperature side interface temperature Tbh is equal to the upper limit temperature Tmax. The upper limit penetrating heat quantity Wmax can be determined based on a difference ΔTbhmmax between the temperature measuring point temperature Tm and the high temperature side interface temperature Tbh (ΔTbhmmax=|Tm−Tmax|) when the high temperature side interface temperature Tbh is equal to the upper limit temperature Tmax, a thermal conductivity λbhm and heat passage area λbhm of a region between the temperature measuring point Dm and the high temperature side interface Bh in the heat flow direction, and a distance Lbhm between the temperature measuring point Dm and the high temperature side interface Bh in the heat flow direction.

The upper limit penetrating heat quantity Wmax can be calculated by a formula (9) shown below, for example. In the formula (9), the temperature measuring point temperature Tm can be acquired from the temperature detection device 40, and the upper limit temperature Tmax, the thermal conductivity λbhm, the heat passage area λbhm, and the distance (length) Lbhm are known values determined in accordance with a design specification of the fifth apparatus. Namely, a value of the upper limit penetrating heat quantity Wmax be determined uniquely in accordance with the temperature measuring point temperature Tm.

$$\begin{matrix}W max = \frac{λ bhm \times \vert Tm - T max \vert \times Abhm}{LBhm} \\ = \frac{λ bhm \times Δ Tbhm max \times Abhm}{Lbhm}\end{matrix} \qquad ( 9 )$$

By the way, as mentioned above, a location of the temperature measuring point Dm is not limited in particular unless functions as the thermoelectric generation module 10M is spoiled substantially, and it can be an arbitrary position in the high temperature heat source 10H, an arbitrary position in the low temperature heat source 10C, and an arbitrary position in the thermoelectric generation module 10M. Therefore, the temperature measuring point Dm may be located on the high temperature heat source side rather than the high temperature side interface Bh, and it can be located conversely on the low temperature heat source side rather than the high temperature side interface Bh.

In the former case, the upper limit penetrating heat quantity Wmax is magnitude of quantity of heat which moves to the high temperature side interface Bh from the temperature measuring point Dm when the high temperature side interface temperature Tbh is equal to the upper limit temperature Tmax. When the high temperature side interface temperature Tbh is equal to the upper limit temperature Tmax (Tbh=Tmax), the penetrating heat quantity W (calculated by the above-mentioned formula (7), for example) must be equal to the upper limit penetrating heat quantity Wmax. Moreover, when the high temperature side interface temperature Tbh is lower than the upper limit temperature Tmax (Tbh<Tmax), a difference ΔTbhmmax between the temperature measuring point temperature Tm and the high temperature side interface temperature Tbh (ΔTbhmmax=|Tm−Tmax|) becomes larger as compared with a case where the high temperature side interface temperature Tbh is equal to the upper limit temperature Tmax (Tbh=Tmax). Therefore, at this time point, the penetrating heat quantity W (calculated by the above-mentioned formula (7), for example) at this time point must be larger than the upper limit penetrating heat quantity Wmax. On the contrary, when the high temperature side interface temperature Tbh is higher than the upper limit temperature Tmax (Tbh>Tmax), the difference ΔTbhmmax between the temperature measuring point temperature Tm and the high temperature side interface temperature Tbh (ΔTbhmmax=|Tm−Tmax|) becomes smaller as compared with a case where the high temperature side interface temperature Tbh is equal to the upper limit temperature Tmax (Tbh=Tmax). Therefore, the penetrating heat quantity W (calculated by the above-mentioned formula (7), for example) at this time must be smaller than the upper limit penetrating heat quantity Wmax.

On the other hand, in the latter case, the upper limit penetrating heat quantity Wmax is magnitude of quantity of heat which moves to the temperature measuring point Dm from the high temperature side interface Bh when the high temperature side interface temperature Tbh is equal to the upper limit temperature Tmax. Also in this case, when the high temperature side interface temperature Tbh is equal to the upper limit temperature Tmax (Tbh=Tmax), the penetrating heat quantity W (calculated by the above-mentioned formula (7), for example) must be equal to the upper limit penetrating heat quantity Wmax. Moreover, when the high temperature side interface temperature Tbh is lower than the upper limit temperature Tmax (Tbh<Tmax), a difference ΔTbhmmax between the temperature measuring point temperature Tm and the high temperature side interface temperature Tbh (ΔTbhmmax=|Tm−Tmax|) becomes smaller as compared with a case where the high temperature side interface temperature Tbh is equal to the upper limit temperature Tmax (Tbh=Tmax). Therefore, the penetrating heat quantity W computed at this time (for example, formula (7) mentioned above) must be smaller than the upper limit penetrating heat quantity Wmax. On the contrary, a difference (ΔTbhmmax=|Tm−Tmax|) of the temperature measuring point temperature Tm and the high temperature side interface temperature Tbh becomes large when the high temperature side interface temperature Tbh is higher than the upper limit temperature Tmax (Tbh>Tmax) with comparing a case where the high temperature side interface temperature Tbh is equal to the upper limit temperature Tmax (Tbh=Tmax). Therefore, the penetrating heat quantity W (calculated by the above-mentioned formula (7), for example) at this time point must be larger than the upper limit penetrating heat quantity Wmax.

Therefore, as described in the above-mentioned (n), the control part Uc is configured so as to judge that the high temperature side interface temperature Tbh is higher than the upper limit temperature Tmax when the penetrating heat quantity W is smaller than the upper limit penetrating heat quantity Wmax in a case where the temperature measuring point Dm is closer to the high temperature heat source 10H than the high temperature side interface Bh and judge that the high temperature side interface temperature Tbh is higher than the upper limit temperature Tmax when the penetrating heat quantity W is larger than the upper limit penetrating heat quantity Wmax in a case where the temperature measuring point Dm is closer to the low temperature heat source 10C than the high temperature side interface Bh.

### Effects

As the above, the fifth apparatus calculates upper limit penetrating heat quantity Wmax that is the penetrating heat quantity when the high temperature side interface temperature Tbh is equal to the upper limit temperature Tmax, determines the penetrating heat quantity W at that time point similarly to the above-mentioned fourth apparatus, and judges whether the high temperature side interface temperature Tbh is higher than the upper limit temperature Tmax or not by comparing them (the upper limit penetrating heat quantity Wmax and the penetrating heat quantity W). Therefore, in the fifth apparatus, the above-mentioned judgement is carried out without determining the high temperature side interface temperature Tbh itself. Namely, in accordance with the fifth apparatus, the arithmetic processing load for judging whether the high temperature side interface temperature Tbh is higher than the upper limit temperature Tmax or not can be reduced.

### Sixth Embodiment

Hereafter, a thermoelectric generation apparatus according to a sixth embodiment of the present invention (which may be referred to as a “sixth apparatus” hereafter) will be explained.

<Configuration>

As mentioned above, the fifth apparatus determines the penetrating heat quantity W based on the heat source temperature difference ΔTs determined from the output related values Mout at a certain time point and judges whether the high temperature side interface temperature Tbh is higher than the upper limit temperature Tmax or not by comparing the penetrating heat quantity W with the upper limit penetrating heat quantity Wmax that is penetrating heat quantity when the high temperature side interface temperature Tbh is equal to the upper limit temperature Tmax. However, it can be judged whether the high temperature side interface temperature Tbh is higher than the upper limit temperature Tmax or not, without determining the penetrating heat quantity W, when the low temperature heat source temperature Tc is maintained at a constant temperature.

Therefore, the sixth apparatus determines the heat source temperature difference ΔTs from the output related values Mout at a certain time point, compares the heat source temperature difference ΔTs with the upper limit heat source temperature difference ΔTmax that is a heat source temperature difference when the high temperature side interface temperature Tbh is equal to the upper limit temperature Tmax, and thereby judges whether the high temperature side interface temperature Tbh is higher than the upper limit temperature Tmax or not, on the premise that the low temperature heat source temperature Tc is maintained at a constant temperature.

Specifically, the sixth apparatus has the same configuration as that of the above-mentioned first apparatus except for points described in the following (e), (h) to (j), (m), (o) and (p). In addition, the following (e) is the same as the (e) in the above-mentioned third apparatus, the following (h) to (j) are the same as the (h) to (j) in the above-mentioned fourth apparatus and fifth apparatus, and the following (m) is the same as the (m) in the above-mentioned fifth apparatus.

(e) A low temperature side temperature measuring point temperature Tmc that is a temperature of a low temperature side temperature measuring point Dmc that is at least one position included in the low temperature heat source 10C is maintained at a constant temperature.

(h) The sixth apparatus further comprises an output detection device 20 which detects output related values Mout that are a set of a plurality of detection values consisting of an output power value P that is magnitude of electric power output from the thermoelectric generation module 10M, an output current value I that is magnitude of electric current output from the thermoelectric generation module 10M and/or an output voltage value V that is magnitude of electric voltage output from the thermoelectric generation module 10M.

(i) The control part Uc has previously stored first characteristic data that is data representing a relation between the heat source temperature difference ΔTs and the output related values Mout.

(j) The control part Uc is configured so as to determine the heat source temperature difference ΔTs based on the first characteristic data from the output related values Mout detected by the output detection device 20.

(m) The control part Uc is configured so as to determine the upper limit penetrating heat quantity Wmax that is magnitude of quantity of heat which moves to the high temperature side interface Bh from the temperature measuring point Dm when the high temperature side interface temperature Tbh is equal to the upper limit temperature Tmax, based on a difference between the temperature measuring point temperature Tm and the high temperature side interface temperature Tbh when the high temperature side interface temperature Tbh is equal to the upper limit temperature Tmax, a thermal conductivity λbhm and heat passage area λbhm of a region between the temperature measuring point Dm and the high temperature side interface Bh in a heat flow direction (that is a flow direction of heat which moves to the low temperature heat source 10C from the high temperature heat source 10H via the thermoelectric generation module 10M) and a distance Lbhm between the temperature measuring point Dm and the high temperature side interface Bh in the heat flow direction.

(o) The control part Uc is configured so as to determine the upper limit heat source temperature difference ΔTmax that is a temperature difference between the high temperature heat source 10H and the low temperature heat source 10C when the high temperature side interface temperature Tbh is equal to the upper limit temperature Tmax, based on the upper limit penetrating heat quantity Wmax, a thermal conductivity λs and heat passage area As of a region where the heat source temperature difference ΔTs is produced and a length Ls of the region where the heat source temperature difference ΔTs is produced in the heat flow direction.

(p) The control part Uc is configured so as to judge that the high temperature side interface temperature Tbh is higher than the upper limit temperature Tmax when the heat source temperature difference ΔTs is larger than the upper limit heat source temperature difference ΔTmax.

Although the explanation here anew is omitted as for the above-mentioned (e) since it is the same as the (e) in the third apparatus and the above-mentioned (h) to (j) are the same as the (h) to (j) in the fourth apparatus and the fifth apparatus as mentioned above, the heat source temperature difference ΔTs can be determined as described in the above-mentioned (j). Moreover, although the explanation here anew is omitted as for the above-mentioned (m) since it is the same as the (m) in the fifth apparatus, the upper limit penetrating heat quantity Wmax can be determined as described in the above-mentioned (m).

Furthermore, the control part Uc is configured so as to determine the upper limit heat source temperature difference ΔTmax, as described in the above-mentioned (o). The upper limit heat source temperature difference ΔTmax is a temperature difference between the high temperature heat source 10H and the low temperature heat source 10C when the high temperature side interface temperature Tbh is equal to the upper limit temperature Tmax. The upper limit heat source temperature difference ΔTmax can be determined based on the upper limit penetrating heat quantity Wmax, the thermal conductivity λs and heat passage area As of the region where the heat source temperature difference ΔTs is produced and the length of the region where the above-mentioned heat source temperature difference is produced in the above-mentioned heat flow direction.

The upper limit heat source temperature difference ΔTmax can be calculated by a formula (10) shown below, for example. In the formula (10), the upper limit penetrating heat quantity Wmax can be determined as described in the above-mentioned (m), and the thermal conductivity λs, the heat passage area As and the distance (length) Ls are known values determined in accordance with a design specification of the sixth apparatus.

$$Δ T max = \frac{W max \times Ls}{λ s \times As} \qquad ( 10 )$$

As the above, the upper limit heat source temperature difference ΔTmax is the temperature difference between the high temperature heat source 10H and the low temperature heat source 10C when the high temperature side interface temperature Tbh is equal to the upper limit temperature Tmax. Moreover, in the sixth apparatus, as described in the above-mentioned (e), the low temperature side temperature measuring point temperature Tmc that is the temperature of the low temperature side temperature measuring point Dmc that is at least one position included in the low temperature heat source 10C is maintained at a constant temperature. In other words, the temperature of the low temperature heat source 10C (low temperature heat source temperature Tc) is maintained at a constant temperature.

Therefore, when the high temperature side interface temperature Tbh is equal to the upper limit temperature Tmax (Tbh=Tmax), the heat source temperature difference ΔTs determined based on the first characteristic data from the output related values Mout detected by the output detection device 20 as described in the above-mentioned (j) must be equal to the upper limit heat source temperature difference ΔTmax. Moreover, when the high temperature side interface temperature Tbh is lower than the upper limit temperature Tmax (Tbh<Tmax), the heat source temperature difference ΔTs becomes smaller as compared with a case where the high temperature side interface temperature Tbh is equal to the upper limit temperature Tmax (Tbh=Tmax). Therefore, the heat source temperature difference ΔTs determined as mentioned above at this time must be smaller than the upper limit heat source temperature difference ΔTmax. On the contrary, when the high temperature side interface temperature Tbh is higher than the upper limit temperature Tmax (Tbh>Tmax), the heat source temperature difference ΔTs becomes larger as compared with a case where the high temperature side interface temperature Tbh is equal to the upper limit temperature Tmax (Tbh=Tmax). Therefore, the heat source temperature difference ΔTs determined as mentioned above at this time must be larger than the upper limit heat source temperature difference ΔTmax.

Therefore, as described in the above-mentioned (p), the control part Uc is configured so as to judge that the high temperature side interface temperature Tbh is higher than the upper limit temperature Tmax when the heat source temperature difference ΔTs is larger than the upper limit heat source temperature difference ΔTmax.

### Effects

As the above, in the sixth apparatus, the low temperature heat source temperature Tc is maintained at a constant temperature. Then, the sixth apparatus calculates the upper limit heat source temperature difference ΔTmax that is a temperature difference between the high temperature heat source 10H and the low temperature heat source 10C when the high temperature side interface temperature Tbh is equal to the upper limit temperature Tmax, determines the heat source temperature difference ΔTs at that time point similarly to the above-mentioned fourth apparatus and fifth apparatus, and judged whether the high temperature side interface temperature Tbh is higher than the upper limit temperature Tmax or not by comparing them (the upper limit heat source temperature difference ΔTmax and the heat source temperature difference ΔTs). Therefore, in the sixth apparatus, the above-mentioned judgement is carried out without determining the high temperature side interface temperature Tbh itself. Namely, in accordance with the sixth apparatus, the arithmetic processing load for judging whether the high temperature side interface temperature Tbh is higher than the upper limit temperature Tmax or not can be reduced.

### Seventh Embodiment

Hereafter, a thermoelectric generation apparatus according to a seventh embodiment of the present invention (which may be referred to as a “seventh apparatus” hereafter) will be explained.

### Configuration

As mentioned above, the sixth apparatus determines the heat source temperature difference ΔTs from the output related values Mout at a certain time point, compares the heat source temperature difference ΔTs with the upper limit heat source temperature difference ΔTmax that is a heat source temperature difference when the high temperature side interface temperature Tbh is equal to the upper limit temperature Tmax, and thereby judges whether the high temperature side interface temperature Tbh is higher than the upper limit temperature Tmax or not, on the premise that the low temperature heat source temperature Tc is maintained at a constant temperature. Namely, in the sixth apparatus, the heat source temperature difference ΔTs determined from the output related values Mout is adopted as an index for judging whether the high temperature side interface temperature Tbh is higher than the upper limit temperature Tmax or not.

By the way, as shown in the graphs of FIG. 2 and FIG. 4, for example, the output related values Mout (namely, the output power value P, and the output current value I and/or the output voltage value V) detected at a certain time point have values corresponding to a plot on a curve according to the heat source temperature difference ΔTs at that time point. Moreover, as shown in the graphs of FIG. 3 and FIG. 5, for example, the curve representing the relation between the output power value P and the output voltage value V and the curve representing the relation between the output power value P and the output current value I shift in a direction in which the output power value P becomes larger as the heat source temperature difference ΔTs becomes larger.

Therefore, in a case where the low temperature heat source temperature Tc is maintained at a constant temperature, the plot corresponding to the output related values Mout when the high temperature side interface temperature Tbh is higher than the upper limit temperature Tmax must be located on a side where the output power value P is larger than a curve when heat source temperature difference ΔTs is equal to the upper limit heat source temperature difference ΔTmax (outside of the curve). On the other hand, the plot corresponding to the output related values Mout when the high temperature side interface temperature Tbh is lower than the upper limit temperature Tmax must be located on a side where the output power value P is smaller than the curve when the heat source temperature difference ΔTs equal to the upper limit heat source temperature difference ΔTmax (inside of the curve).

For example, a curve drawn by a solid line in a graph of FIG. 11 is a curve (reference curve CS) representing the relation between the output power value P and the output current value I when the heat source temperature difference ΔTs is equal to the upper limit heat source temperature difference ΔTmax (namely, when the high temperature side interface temperature Tbh is equal to the upper limit temperature Tmax). In a case where the low temperature heat source temperature Tc is maintained at a constant temperature, when the high temperature side interface temperature Tbh is lower than the upper limit temperature Tmax, the heat source temperature difference ΔTs is smaller than the upper limit heat source temperature difference ΔTmax. Therefore, a curve representing the relation between the output power value P and the output current value I at this time point exists on a side where the output power value P is smaller with respect to the reference curve CS (inside of the reference curve CS) like the curve CL drawn by a broken line. Namely, the plot corresponding to the output related values Mout when the high temperature side interface temperature Tbh is lower than the upper limit temperature Tmax should exist inside of the reference curve CS (hatched area).

On the other hand, when the high temperature side interface temperature Tbh is higher than the upper limit temperature Tmax, the heat source temperature difference ΔTs is larger than the upper limit heat source temperature difference ΔTmax. Therefore, a curve representing the relation between the output power value P and the output current value I at this time point exists on a side where the output power value P is larger with respect to the reference curve CS (outside of the reference curve CS) like the curve CH drawn by a dashed line. Namely, the plot corresponding to the output related values Mout when the high temperature side interface temperature Tbh is higher than the upper limit temperature Tmax should exist outside of the reference curve CS (on a side where the output power value P is larger than the hatched area).

As mentioned above, it can be judged whether the heat source temperature difference ΔTs at a certain time point is larger than a specific temperature difference in accordance with whether the plot corresponding to the output related values Mout at the time point exists outside (on the side where the output power value P is larger) or inside (on the side where the output power value P is smaller) with respect to the curve representing the relation between the output power value P and the output voltage value V or the curve representing the relation between the output power value P and the output current value I when the heat source temperature difference ΔTs is equal to the upper limit heat source temperature difference ΔTmax (reference curve). Namely, any one of the detection values which constitute the output related values Mout (namely, the output power value P and the output current value I and/or the output voltage value V) may be adopted as an index for judging whether the high temperature side interface temperature Tbh is higher than the upper limit temperature Tmax or not.

Therefore, the seventh apparatus determines an upper limit output power value Pmax that is an output power value when the high temperature side interface temperature Tbh is equal to the upper limit temperature Tmax, compares the upper limit output power value Pmax with the output power value P at that time point, and thereby judges whether the high temperature side interface temperature Tbh is higher than the upper limit temperature Tmax or not, on the premise that the low temperature heat source temperature Tc is maintained at a constant temperature.

Specifically, the seventh apparatus has the same configuration as that of the above-mentioned first apparatus except for points described in the following (e), (h), (i), (m), (o), (q) and (r). In addition, the following (e) is the same as the (e) in the above-mentioned third apparatus and sixth apparatus, the following (h) and (i) are the same as the (h) and (i) in the above-mentioned fourth apparatus to sixth apparatus, the following (m) is the same as the (m) in the above-mentioned fifth apparatus and sixth apparatus, and the following (o) is the same as the (o) in the above-mentioned sixth apparatus.

(e) A low temperature side temperature measuring point temperature Tmc that is a temperature of a low temperature side temperature measuring point Dmc that is at least one position included in the low temperature heat source 10C is maintained at a constant temperature.

(h) The seventh apparatus further comprises an output detection device 20 which detects output related values Mout that are a set of a plurality of detection values consisting of an output power value P that is magnitude of electric power output from the thermoelectric generation module 10M, an output current value I that is magnitude of electric current output from the thermoelectric generation module 10M and/or an output voltage value V that is magnitude of electric voltage output from the thermoelectric generation module 10M.

(i) The control part Uc has previously stored first characteristic data that is data representing a relation between the heat source temperature difference ΔTs and the output related values Mout.

(m) The control part Uc is configured so as to determine the upper limit penetrating heat quantity Wmax that is magnitude of quantity of heat which moves to the high temperature side interface Bh from the temperature measuring point Dm when the high temperature side interface temperature Tbh is equal to the upper limit temperature Tmax, based on a difference between the temperature measuring point temperature Tm and the high temperature side interface temperature Tbh when the high temperature side interface temperature Tbh is equal to the upper limit temperature Tmax, a thermal conductivity λbhm and heat passage area λbhm of a region between the temperature measuring point Dm and the high temperature side interface Bh in a heat flow direction (that is a flow direction of heat which moves to the low temperature heat source 10C from the high temperature heat source 10H via the thermoelectric generation module 10M) and a distance Lbhm between the temperature measuring point Dm and the high temperature side interface Bh in the heat flow direction.

(o) The control part Uc is configured so as to determine the upper limit heat source temperature difference ΔTmax that is a temperature difference between the high temperature heat source 10H and the low temperature heat source 10C when the high temperature side interface temperature Tbh is equal to the upper limit temperature Tmax, based on the upper limit penetrating heat quantity Wmax, a thermal conductivity λs and heat passage area As of a region where the heat source temperature difference ΔTs is produced and a length Ls of the region where the heat source temperature difference ΔTs is produced in the heat flow direction.

(q) The control part Uc is configured so as to determine, based on the first characteristic data, the upper limit output power value Pmax that is magnitude of electric power output from the thermoelectric generation module 10M when the heat source temperature difference ΔTs is equal to the upper limit heat source temperature difference ΔTmax and the output current value I and/or output voltage value V are equal to the output current value I and/or output voltage value V detected by the output detection device 20.

(r) The control part Uc is configured so as to judge that the high temperature side interface temperature Tbh is higher than the upper limit temperature Tmax when the output power value P detected by the output detection device 20 is larger than the upper limit output power value Pmax.

Although the explanation here anew is omitted as for the above-mentioned (e), (h), (i), (m) and (o) since the above-mentioned (e) is the same as the (e) in the third apparatus and the sixth apparatus, the above-mentioned (h) and (i) are the same as the (h) and (i) in the fourth apparatus to the sixth apparatus, the above-mentioned (m) is the same as the (m) in the fifth apparatus and the sixth apparatus, and the above-mentioned (o) is the same as the (o) in the sixth apparatus, as mentioned above, the upper limit heat source temperature difference ΔTmax can be determined as described in the above-mentioned (o).

Furthermore, as described in the above-mentioned (q), the control part Uc is configured so as to determine the upper limit output power value Pmax. The upper limit output power value Pmax is magnitude of electric power output from the thermoelectric generation module 10M when the heat source temperature difference ΔTs is equal to the upper limit heat source temperature difference ΔTmax and the output current value I and/or output voltage value V are equal to the output current value I and/or output voltage value V detected by the output detection device 20. Moreover, the upper limit heat source temperature difference ΔTmax is a temperature difference between the high temperature heat source 10H and the low temperature heat source 10C when the high temperature side interface temperature Tbh is equal to the upper limit temperature Tmax. Namely, the upper limit output power value Pmax is an output power value which will be output from the thermoelectric generation module 10M when the output current value I and/or output voltage value V are equal to the output current value I and/or output voltage value V detected by the output detection device 20 in a case where the high temperature side interface temperature Tbh is equal to the upper limit temperature Tmax. In other words, the upper limit output power value Pmax is an output power value which should be output from the thermoelectric generation module 10M when the high temperature side interface temperature Tbh is equal to the upper limit temperature Tmax in a case where the output current value I and/or output voltage value V are equal to the output current value I and/or output voltage value V detected by the output detection device 20.

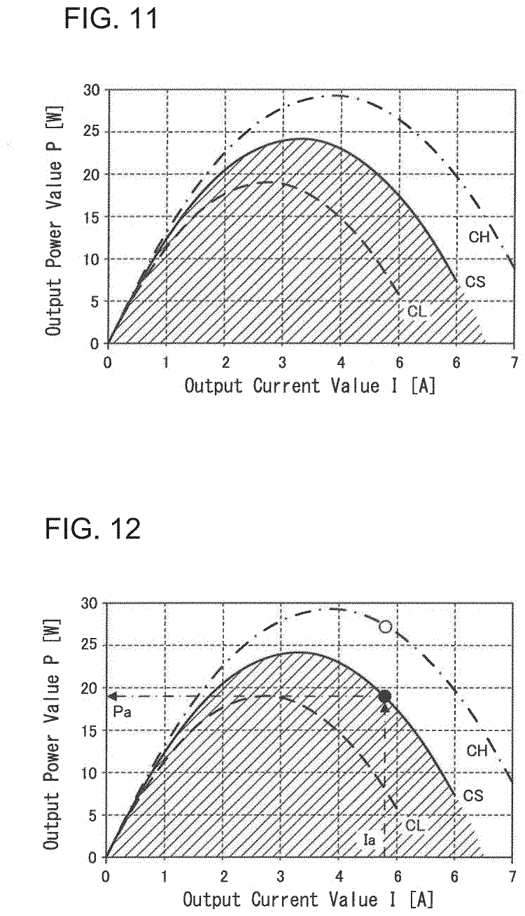

The upper limit output power value Pmax is determined as follows, for example. First, (the CPU included in) the control part Uc extracts the relation between the output current value I and/or output voltage value V and the output power value P when the upper limit heat source temperature difference ΔTmax determined as described in the above mentioned (o) is equal to the heat source temperature difference ΔT from the first characteristic data. Specifically, the relation between the output current value I and the output power value P represented by the reference curve CS shown in FIG. 12 corresponds to this relation, for example.

Then, based on the relation between the output current value I and/or output voltage value V and the output power value P extracted as mentioned above, the output power value P corresponding to the output current value I and/or output voltage value V detected by the output detection device 20 can be determined as the upper limit output power value Pmax. Specifically, the output power value Pa corresponding to the output current value Ia is determined as the upper limit output power value Pmax, based on the relation between the output current value I and the output power value P represented by the reference curve CS, from the output current value Ia detected by the output detection device 20 at the time point, as shown in FIG. 12, for example.

As mentioned above, the upper limit output power value Pmax is an output power value which should be output from the thermoelectric generation module 10M when the heat source temperature difference ΔTs is equal to the upper limit heat source temperature difference ΔTmax in a case where the output current value I and/or the output voltage value V are equal to the output current value I and/or the output voltage value V detected by the output detection device 20. Moreover, in the seventh apparatus, the low temperature side temperature measuring point temperature Tmc that is the temperature of the low temperature side temperature measuring point Dmc that is at least one position included in the low temperature heat source 10C is maintained at a constant temperature, as described in the above-mentioned (e). In other words, the temperature of the low temperature heat source 10C (low temperature heat source temperature Tc) is maintained at a constant temperature.

Therefore, when the high temperature side interface temperature Tbh is equal to the upper limit temperature Tmax (Tbh=Tmax), the output power value P detected by the output detection device 20 must be equal to the upper limit output power value Pmax. Moreover, when the high temperature side interface temperature Tbh is lower than the upper limit temperature Tmax (Tbh<Tmax), the heat source temperature difference ΔTs becomes smaller as compared with a case where the high temperature side interface temperature Tbh is equal to the upper limit temperature Tmax (Tbh=Tmax). Therefore, the output power value P detected by the output detection device 20 at this time must be smaller than the upper limit output power value Pmax (the corresponding plot of the output related values Mout should exist inside the reference curve CS). On the contrary, when the high temperature side interface temperature Tbh is higher than the upper limit temperature Tmax (Tbh>Tmax), the heat source temperature difference ΔTs becomes larger as compared with a case where the high temperature side interface temperature Tbh is equal to the upper limit temperature Tmax (Tbh=Tmax). Therefore, the output power value P detected by the output detection device 20 at this time must be larger than the upper limit output power value Pmax (the corresponding plot of the output related values Mout should exist outside the reference curve CS) (refer to an outlined round mark in FIG. 12).

Then, the control part Uc is configured so as to judge that the high temperature side interface temperature Tbh is higher than the upper limit temperature Tmax when the output power value P detected by the output detection device 20 is larger than the upper limit output power value Pmax, as described in the above mentioned (r).

### Effects

As the above, in the seventh apparatus, the low temperature heat source temperature Tc is maintained at a constant temperature. Therefore, the seventh apparatus determines the upper limit output power value Pmax that is an output power value which will be output from the thermoelectric generation module 10M when the output current value I and/or the output voltage value V are equal to the output current value I and/or the output voltage value V detected by the output detection device 20 in a case where the high temperature side interface temperature Tbh is equal to the upper limit temperature Tmax, detects the output power value P actually output from the thermoelectric generation module 10M at that time point by the output detection device 20 similarly to the above-mentioned fourth apparatus or sixth apparatus, and judges whether the high temperature side interface temperature Tbh is higher than the upper limit temperature Tmax or not by comparing them (the upper limit output power value Pmax and the output power value P). Therefore, in the seventh apparatus, the above-mentioned judgement is carried out without determining the high temperature side interface temperature Tbh itself. Namely, in accordance with the seventh apparatus, the arithmetic processing load for judging whether the high temperature side interface temperature Tbh is higher than the upper limit temperature Tmax or not can be reduced.

### Eighth Embodiment

Hereafter, a thermoelectric generation apparatus according to an eighth embodiment of the present invention (which may be referred to as an “eighth apparatus” hereafter) will be explained.

<Configuration>

As mentioned above, the seventh apparatus determines the upper limit output power value Pmax that is the output power value when the high temperature side interface temperature Tbh is equal to the upper limit temperature Tmax, detects the output power value P at that time point, and judges whether the high temperature side interface temperature Tbh is higher than the upper limit temperature Tmax or not by comparing them (the upper limit output power value Pmax and the output power value P), on the premise that the low temperature heat source temperature Tc is maintained at a constant temperature. Namely, in the seventh apparatus, the output power value P that is one of the detection values which constitute the output related values Mout is adopted as an index for judging whether the high temperature side interface temperature Tbh is higher than the upper limit temperature Tmax or not. However, other detection values (namely, the output current value I and/or the output voltage value V) which constitute the output related values Mout may be adopted as the index.

Then, the eighth apparatus determines upper limit output related values Mmax that are an output current value and/or an output voltage value when the high temperature side interface temperature Tbh is equal to the upper limit temperature Tmax, and judges whether the high temperature side interface temperature Tbh is higher than the upper limit temperature Tmax or not by comparing the upper limit output related values Mmax with the corresponding output related values Mout at that time point.

Specifically, the eighth apparatus has the same configuration as that of the above-mentioned first apparatus except for points described in the following (e), (h) and (i), (m) and (o), and (s). In addition, the following (e) is the same as the (e) in the above-mentioned third apparatus, sixth apparatus and seventh apparatus, the following (h) and (i) are the same as the (h) and (i) in the above-mentioned fourth apparatus to seventh apparatus, the following (m) is the same as the (m) in the above-mentioned fifth apparatus to seventh apparatus, and the following (o) is the same as the (o) in the above-mentioned sixth apparatus and seventh apparatus. Namely, the eighth apparatus has the same configuration as that of the above-mentioned seventh apparatus except that the eighth apparatus has a technical feature described in the following (s) in place of those described in the above-mentioned (q) and (r).

(e) A low temperature side temperature measuring point temperature Tmc that is a temperature of a low temperature side temperature measuring point Dmc that is at least one position included in the low temperature heat source 10C is maintained at a constant temperature.

(h) The eighth apparatus further comprises an output detection device 20 which detects output related values Mout that are a set of a plurality of detection values consisting of an output power value P that is magnitude of electric power output from the thermoelectric generation module 10M, an output current value I that is magnitude of electric current output from the thermoelectric generation module 10M and/or an output voltage value V that is magnitude of electric voltage output from the thermoelectric generation module 10M.

(i) The control part Uc has previously stored first characteristic data that is data representing a relation between the heat source temperature difference ΔTs and the output related values Mout.

(m) The control part Uc is configured so as to determine the upper limit penetrating heat quantity Wmax that is magnitude of quantity of heat which moves to the high temperature side interface Bh from the temperature measuring point Dm when the high temperature side interface temperature Tbh is equal to the upper limit temperature Tmax, based on a difference between the temperature measuring point temperature Tm and the high temperature side interface temperature Tbh when the high temperature side interface temperature Tbh is equal to the upper limit temperature Tmax, a thermal conductivity λbhm and heat passage area λbhm of a region between the temperature measuring point Dm and the high temperature side interface Bh in a heat flow direction (that is a flow direction of heat which moves to the low temperature heat source 10C from the high temperature heat source 10H via the thermoelectric generation module 10M) and a distance Lbhm between the temperature measuring point Dm and the high temperature side interface Bh in the heat flow direction.

(o) The control part Uc is configured so as to determine the upper limit heat source temperature difference ΔTmax that is a temperature difference between the high temperature heat source 10H and the low temperature heat source 10C when the high temperature side interface temperature Tbh is equal to the upper limit temperature Tmax, based on the upper limit penetrating heat quantity Wmax, a thermal conductivity λs and heat passage area As of a region where the heat source temperature difference ΔTs is produced and a length Ls of the region where the heat source temperature difference ΔTs is produced in the heat flow direction.

(s) The control part Uc is configured so as to judge that the high temperature side interface temperature Tbh is higher than the upper limit temperature Tmax when the upper limit output related values Mmax that is the output current I and/or the output voltage V output from the thermoelectric generation module 10M is not determined based on the first characteristic data in a case where the heat source temperature difference ΔTs is equal to the upper limit heat source temperature difference ΔTmax and the output power value P is equal to the output power value P detected by the output detection device 20 or when the upper limit output related values Mmax is determined based on the first characteristic data and the output current value I and/or the output voltage value V detected by the output detection device 20 are larger or smaller than any of the upper limit output related values Mmax.

Although the explanation here anew is omitted as for the above-mentioned (e), (h) and (i), (m) and (o) since the above-mentioned (e) is the same as the (e) in the third apparatus, sixth apparatus and seventh apparatus, the above-mentioned (h) and (i) are the same as the (h) and (i) in the fourth apparatus to seventh apparatus, the above-mentioned (m) is the same as the (m) in the fifth apparatus to seventh apparatus, and the above-mentioned (o) is the same as the (o) in the sixth apparatus and seventh apparatus as mentioned above, the upper limit heat source temperature difference ΔTmax can be determined as described in the above-mentioned (o).

Furthermore, as described in the above-mentioned (s), the control part Uc is configured so as to judge that the high temperature side interface temperature Tbh is higher than the upper limit temperature Tmax when the upper limit output related values Mmax is not determined based on the first characteristic data or when the upper limit output related values Mmax is determined based on the first characteristic data and the output current value I and/or the output voltage value V detected by the output detection device 20 are larger or smaller than any of the upper limit output related values Mmax.

The upper limit output related values Mmax is the output current value I and/or the output voltage value V which will be output from the thermoelectric generation module 10M when the heat source temperature difference ΔTs is equal to the upper limit heat source temperature difference ΔTmax and the output power value P is equal to the output power value P detected by the output detection device 20.

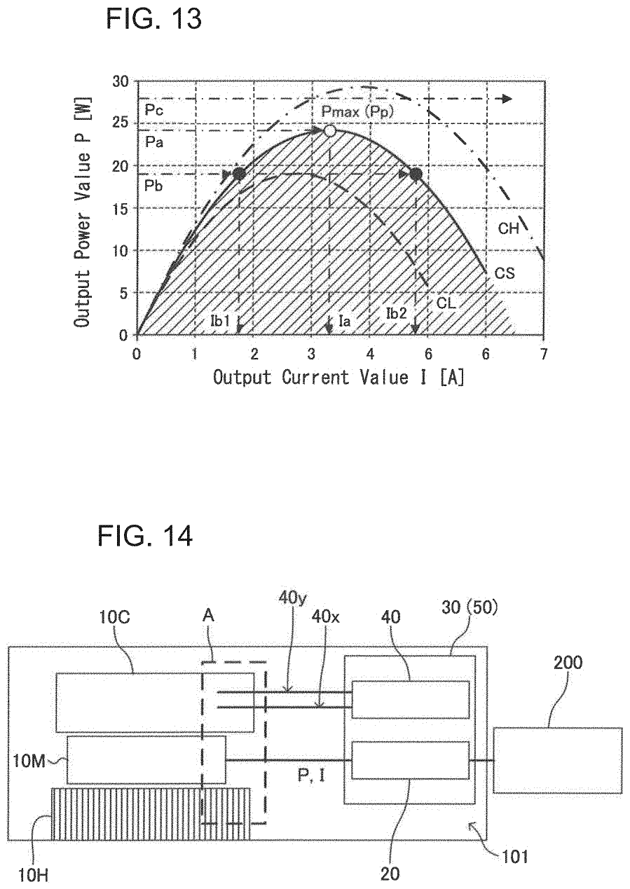

For example, as shown in FIG. 13, in a case where the output power value Pa detected by the output detection device 20 at a certain time point is equal to the maximum output power value Pp when the heat source temperature difference ΔTs is equal to the upper limit heat source temperature difference ΔTmax (namely, a critical output power value Pmax) (refer to the outlined round mark), there is the sole output current value Ia and/or output voltage value Va (not shown) which will be output from the thermoelectric generation module 10M. As explained referring to FIG. 11 regarding the seventh apparatus, a plot of the output related values Mout when the high temperature side interface temperature Tbh is higher than the upper limit temperature Tmax exists outside the reference curve CS. Therefore, when the high temperature side interface temperature Tbh at this time point is higher than the upper limit temperature Tmax, the output related values Mout which is larger or smaller than the sole upper limit output related values Mmax (namely, the sole output current value Ia and/or output voltage value Va) determined as mentioned above, are detected by the output detection device 20. In other words, when the output related values Mout which are larger or smaller than the sole upper limit output related values Mmax determined as mentioned above is detected by the output detection device 20, it can be judged that the high temperature side interface temperature Tbh at this time point is higher than the upper limit temperature Tmax.

On the other hand, when the output power value Pb detected by the output detection device 20 at a certain time point is smaller than the critical output power value Pmax (refer to the black round mark), there are two output current value Ib and/or output voltage values Vb (not shown) which will be output from the thermoelectric generation module 10M. As the above, a plot of the output related values Mout when the high temperature side interface temperature Tbh is higher than the upper limit temperature Tmax exists outside the reference curve CS. Therefore, when the high temperature side interface temperature Tbh at this time point is higher than the upper limit temperature Tmax, the output related values Mout which are larger or smaller than any of the two upper limit output related values Mmax (namely, the two output current values Ia and/or output voltage values Va) determined as mentioned above are detected by the output detection device 20. In other words, when the output related values Mout larger or smaller than any of the two upper limit output related values Mmax determined as mentioned above are detected by the output detection device 20, it can be judged that the high temperature side interface temperature Tbh at this time point is higher than the upper limit temperature Tmax.

Furthermore, when an output power value Pc detected by the output detection device 20 at a certain time point is larger than the critical output power value Pmax, is impossible to determine the output current value and/or output voltage value which will be output from the thermoelectric generation module 10M based on the first characteristic data (no corresponding point exists on the reference curve CS). Also in this case, it can be judged that the high temperature side interface temperature Tbh at this time point is higher than the upper limit temperature Tmax.

Therefore, as mentioned above, the control part Uc which the eighth apparatus comprises is configured so as to judge that the high temperature side interface temperature Tbh is higher than the upper limit temperature Tmax in the following two cases.

(I) When the upper limit output related values Mmax that are the output current I and/or output voltage V output from the thermoelectric generation module 10M are not determined based on the first characteristic data in a case where the heat source temperature difference ΔTs is equal to the upper limit heat source temperature difference ΔTmax and the output power value P is equal to the output power value P detected by the output detection device, or

(II) When the upper limit output related values Mmax is determined based on the first characteristic data and the output current value I and/or output voltage value V detected by the output detection device 20 are larger or smaller than any of the upper limit output related values Mmax.

### Effects

As the above, in the eighth apparatus, the low temperature heat source temperature Tc is maintained at a constant temperature. Therefore, the eighth apparatus judges whether the high temperature side interface temperature Tbh is higher than the upper limit temperature Tmax or not based on the upper limit output related values Mmax that are the output current I and/or output voltage V which will be output from the thermoelectric generation module 10M when the output power value P is equal to the output power value P detected by the output detection device 20 in a case where the high temperature side interface temperature Tbh is equal to the upper limit temperature Tmax. Accordingly, in the eighth apparatus, the above-mentioned judgement is carried out without determining the high temperature side interface temperature Tbh itself. Namely, in accordance with the eighth apparatus, the arithmetic processing load for judging whether the high temperature side interface temperature Tbh is higher than the upper limit temperature Tmax or not can be reduced.

### Ninth Embodiment

Hereafter, a thermoelectric generation apparatus according to a ninth embodiment of the present invention (which may be referred to as a “ninth apparatus” hereafter) will be explained.

<Configuration>

As mentioned above, in the thermoelectric generation apparatus according to the present invention (present invention apparatus), the control part Uc may be configured so as to perform the output maximize control in which the output adjustment device 30 is controlled to change the output current value I and/or the output voltage value V such that the output power value P becomes the maximum when the high temperature side interface temperature Tbh is judged to be the predetermined upper limit temperature Tmax or less. In this case, as will be mentioned in detail later, the arithmetic processing load for judging whether the high temperature side interface temperature Tbh is higher than the upper limit temperature Tmax or not can be reduced.

Then, the ninth apparatus is any one of the above-mentioned various present invention apparatuses including the first apparatus to the eighth apparatus explained so far, and further has features described in the following (t) to (w).

(t) The control part Uc is configured so as to perform output maximize control that is control in which the output adjustment device 30 is controlled to change the output current value I and/or the output voltage value V such that the output power value P becomes the maximum when it is judged that the high temperature side interface temperature Tbh is the upper limit temperature Tmax or less.

As a specific example of the output maximize control, the above-mentioned “maximum power point tracking” (MPPT) can be mentioned. The maximum power point tracking (MPPT) is a method in which the output power value P is maximized by gradually increasing the output current value I from the power generation module through electric current control of a controller and further increasing the output current value I when the output power value P increases in connection with this while reducing the output current value I when the output power value P decreases conversely, for example.

(u) The control part Uc has stored second characteristic data that is data representing a relation between the heat source temperature difference ΔTs when performing the output maximize control and an index detection value Mindex that is at least one detection value of a plurality of the detection values included in the output related values Mout, as the first characteristic data.

The second characteristic data can be also acquired through a pre-experimentation using the ninth apparatus, etc., similarly to the first characteristic data. Moreover, the second characteristic data can be also stored in a storage unit such as a memory (ROM) which the control part comprises, similarly to the first characteristic data.

The second characteristic data is not limited in particular, as long as it is data representing the relation between the heat source temperature difference ΔTs and the index detection value Mindex. For example, the second characteristic data may be one data table or one data map representing a relation between the heat source temperature difference ΔTs and the specific output current value Ip or output voltage value Vp corresponding to the maximum output power value Pp. Alternatively, the second characteristic data may be one function representing a relation between the heat source temperature difference ΔTs and the specific output current value Ip or output voltage value Vp corresponding to the maximum output power value Pp.

Anyway, the output power value P, output current value I and output voltage value V corresponding to each heat source temperature difference ΔTs is determined uniquely in association with execution of the output maximize control. Therefore, as compared with the first characteristic data in which the output power value P, output current value I and output voltage value V change in each heat source temperature difference ΔTs, information quantity of the second characteristic data is smaller, and capacity of a storage medium for storing the second characteristic data can be reduced. Moreover, arithmetic processing for determining the heat source temperature difference ΔTs and/or the upper limit heat source temperature difference ΔTmax can be simplified.

(v) The control part Uc is configured so as to determine the heat source temperature difference ΔTs based on the second characteristic data from the index detection value Mindex detected by the output detection device 20.

As the above, in the ninth apparatus, when the high temperature side interface temperature Tbh is judged to be the upper limit temperature Tmax or less, the output maximize control is performed, and the output current value I and/or the output voltage value V are controlled such that the output power value P becomes the maximum in accordance with the heat source temperature difference ΔTs at each occasion. In other words, the output adjustment device 30 is controlled so as to attain the specific output current value Ip (and specific output voltage value Vp) shown in FIG. 2 according to each heat source temperature difference ΔTs, and the corresponding maximum output power value Pp is attained. Namely, the output power value P, the output current value I and the output voltage value V corresponding to each heat source temperature difference ΔTs are determined uniquely.

Therefore, in the ninth apparatus, the heat source temperature difference ΔTs and/or upper limit heat source temperature difference ΔTmax can be determined based on the index detection value Mindex that is at least one detection value in the set of a plurality of detection values included in the output related values Mout, without referring to the first characteristic data representing the relation between the heat source temperature difference ΔTs, the output power value P and the output current value I and/or output voltage value V in the thermoelectric generation module 10M.

(w) The control part Uc is configured so as to stop execution of the output maximize control and control the output adjustment device 30 to increase the output current value I or decrease the output voltage value V when the high temperature side interface temperature Tbh is judged to be higher than the upper limit temperature Tmax. Namely, the control part Uc is configured so as to perform a control routine in which the high temperature side interface temperature Tbh of the thermoelectric conversion element 10E is lowered by increasing the output current value I or decreasing the output voltage value V (cooling control routine). when the high temperature side interface temperature Tbh is judged to be higher than the upper limit temperature Tmax.

### Effects

In accordance with the ninth apparatus, similarly to the above-mentioned various present invention apparatuses, a thermoelectric generation apparatus can be worked at high generating efficiency while preventing damage of the thermoelectric conversion element 10E since the high temperature heat source side interface temperature Tbh of the thermoelectric conversion element 10E can be lowered quickly and effectively. In addition, in the ninth apparatus, the cooling control routine can be performed using the second characteristic data which has smaller data volume as compared with the first characteristic data as mentioned above. Therefore, the arithmetic processing load for judging whether the high temperature side interface temperature Tbh is higher than the upper limit temperature Tmax or not can be reduced

### Working Example 1

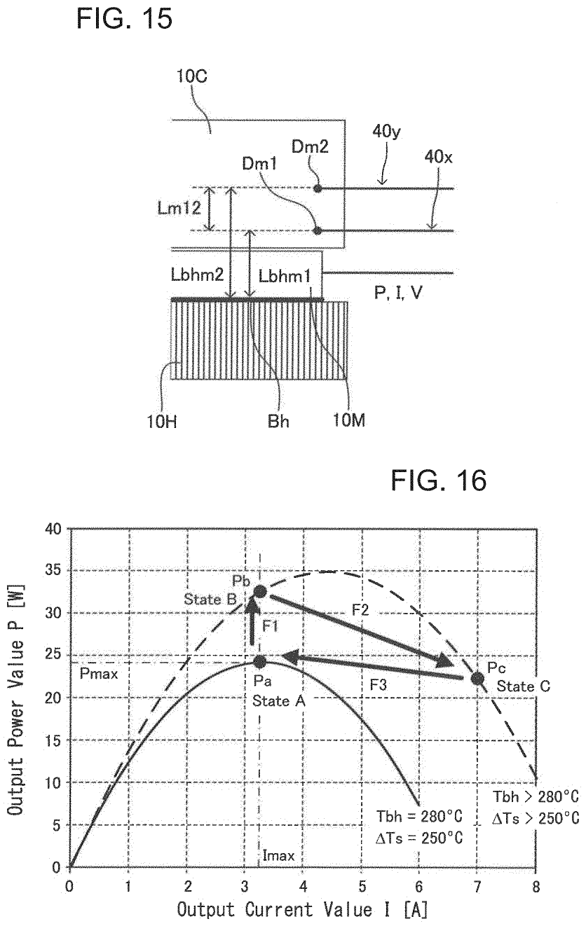

Here, a specific example of a thermoelectric generation apparatus according to a working example 1 of the present invention (which may be referred to as a “working example apparatus 101” hereafter) will be explained in detail below, referring to FIG. 14 and FIG. 15, etc.

FIG. 14 is a schematic view for showing a configuration of the thermoelectric generation apparatus as one specific example of the present invention apparatus (working example apparatus 101). The working example apparatus 101 comprises a thermoelectric generation module 10M, an output detection device 20, an output adjustment device 30, a temperature detection device 40 and a control part 50.

The thermoelectric generation module 10M comprises a thermoelectric conversion element (not shown) which generates electric power by a heat source temperature difference ΔTs that is a temperature difference between a high temperature heat source 10H and a low temperature heat source 10C. As mentioned above, the thermoelectric conversion element is constituted by a series electric circuit formed by a plurality of sets two different kinds of thermoelectric semiconductors electrically connected alternately in series (not shown), and is sandwiched by the high temperature heat source 10H and the low temperature heat source 10C.

The output detection device 20 detects an output power value P that is magnitude of output power that is electric power output from the thermoelectric generation module 10M, an output current value I that is magnitude of electric current output from the thermoelectric generation module 10M and/or an output voltage value V that is magnitude of electric voltage output from the thermoelectric generation module 10M. The output adjustment device 30 changes the output current value I and/or the output voltage value V. The temperature detection device 40 detects a value of state quantity which has correlation with the high temperature side interface temperature Tbh. The control part 50 controls the output adjustment device 30 to control the output current value I and/or the output voltage value V.

In the working example apparatus 101, a DC-DC converter (which will be referred as to a “DC-DC converter 30” hereafter) is connected to the thermoelectric generation module 10M as the output adjustment device 30. Moreover, the DC-DC converter 30 includes the output detection device 20 and the temperature detection device 40, boosts up and smoothes the output power from the thermoelectric generation module 10M, and supplies the electric power to a power supply destination (load) 200, such as a battery. Furthermore, the DC-DC converter 30 functions also as the control part 50.

Two thermocouples 40x and 40y are disposed in the low temperature heat source 10C, and these two thermocouples 40x and 40y are connected to the temperature detection device 40 included in the DC-DC converter 30.

FIG. 15 is a schematic enlarged view for showing a region A surrounded by a broken line in FIG. 14, in which a vicinity of positions where the two thermocouples 40x and 40y are disposed in the low temperature heat source 10C (namely, temperature measuring points Dm1 and Dm2) is shown. The thermocouple 40y is disposed a predetermined distance apart from the thermocouple 40x in a direction in which the high temperature heat source 10H and the low temperature heat source 10C sandwich the thermoelectric generation module 10M (namely, lamination direction thereof). Namely, the temperature detection device 40 which comprises the thermocouples 40x and 40y as temperature sensors is configured so as to respectively detect a first temperature measuring point temperature Tm1 and a second temperature measuring point temperature Tm2 that are temperatures of a first temperature measuring point Dm1 and a second temperature measuring point Dm2 that are two temperature measuring points located a predetermined interval (spacing) Lm12 apart from each other in a heat flow direction that is a flow direction of heat which moves to the low temperature heat source 10C from the high temperature heat source 10H via the thermoelectric generation module 10M.

Moreover, data representing a relation between the output power value VP and the output current value I for each of various heat source temperature differences ΔTs's of the thermoelectric generation module 10M has been stored in a storage unit (not shown) which the DC-DC converter 30 comprises. This data corresponds to the above-mentioned first characteristic data that is data representing the relation between the heat source temperature difference ΔTs, the output power value P, and the output current value I and/or output voltage value V in the thermoelectric generation module 10M.

As mentioned above, the DC-DC converter 30 functions also as the control part 50. A CPU constituting an electronic control unit (ECU) which the DC-DC converter 30 comprises performs processing explained below by performing instructions (routine) stored in a memory (ROM).

The control part 50 calculates the penetrating heat quantity W that is magnitude of heat which moves to the low temperature heat source 10C from the high temperature heat source 10H via the thermoelectric generation module 10M, based on the above-mentioned formula (1), from a difference between temperatures of the two temperature measuring points Dm1 and Dm2 (the first temperature measuring point temperature Tm1 and the second temperature measuring point temperature Tm2) detected by the thermocouples 40x and 40y as temperature sensors, the thermal conductivity λm12 and heat passage area λm12 of the region between the first temperature measuring point Dm1 and the second temperature measuring point Dm2 in the heat flow direction and the distance Lm12 between the first temperature measuring point Dm1 and the second temperature measuring point Dm2 in the heat flow direction. And the control part 50 determines the high temperature side interface temperature Tbh based on the first temperature measuring point temperature Tm1 and/or second temperature measuring point temperature Tm2, the thermal conductivities (λbhm1 and/or λbhm2) and heat passage areas (Abhm1 and/or Abhm2) of a region to the first temperature measuring point Dm1 and/or second temperature measuring point Dm2 from the high temperature side interface Bh in the heat flow direction, the penetrating heat quantity W and the distances (Lbhm1 and/or Lbhm2) to the first temperature measuring point Dm1 and/or second temperature measuring point Dm2 from the high temperature side interface Bh in the heat flow direction. The above-mentioned processing corresponds to step S10 in the above-mentioned flowchart of FIG. 9.

Next, it is judged whether the high temperature side interface temperature Tbh determined as mentioned above is higher than the predetermined upper limit temperature Tmax or not. This processing corresponds to step S20 in the above-mentioned flowchart of FIG. 9.

When the high temperature side interface temperature Tbh is the upper limit temperature Tmax or less, the control part 50 controls the output adjustment device 30 in accordance with a control routine which is to be performed at ordinary time (ordinary control routine) to control the output current value I, as mentioned above. This processing corresponds to step S90 in the above-mentioned flowchart of FIG. 9. On the other hand, when the high temperature side interface temperature Tbh is higher than the upper limit temperature Tmax, the control part 50 performs a control routine in which the high temperature side interface temperature Tbh of the thermoelectric conversion element 10E is lowered by increasing the output current value I (cooling control routine). This processing corresponds to step S30 in the above-mentioned flowchart of FIG. 9.

In accordance with the working example apparatus 101, the CPU constituting the electronic control unit (ECU) which the DC-DC converter 30 comprise repeatedly performs the above-mentioned routine at predetermined time intervals. Thereby, the thermoelectric generation module 10M can be worked at high generating efficiency, while maintaining the high temperature side interface temperature Tbh at the upper limit temperature Tmax or less to prevent damage of the electrothermal power generation element 10E.

### Working Example 2

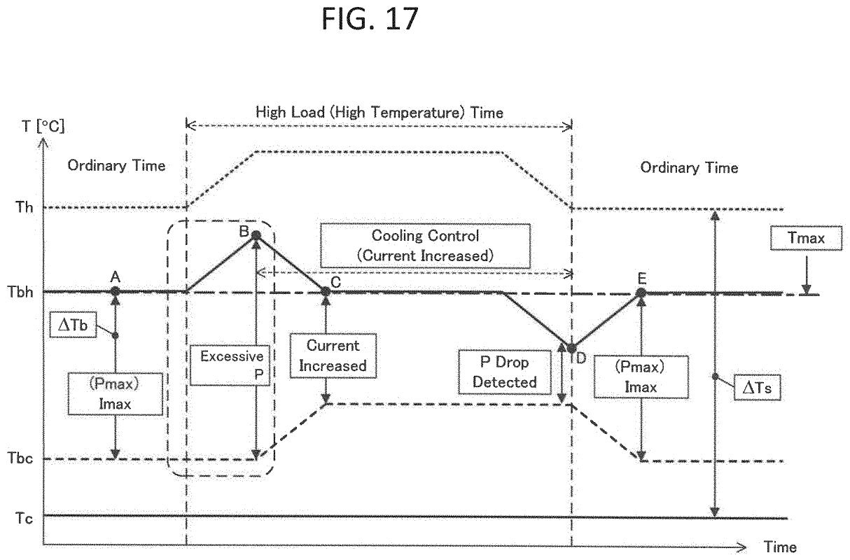

Here, another specific example of a thermoelectric generation apparatus according to a working example of the present invention (which may be referred to as a “working example apparatus 102” hereafter) will be explained in detail below, referring to FIG. 16 and FIG. 17. Basically, the working example apparatus 102 is a thermoelectric generation apparatus which has the same configuration as that of the above-mentioned working example apparatus 101.

However, in the working example apparatus 101, as mentioned above, by comparing the high temperature side interface temperature Tbh and the upper limit temperature Tmax which are computed based on the temperature etc. of the temperature measuring points Dm1 and Dm2 in the low temperature heat source 10C detected by the thermocouples 40x and 40y as temperature sensors constituting the temperature detection device 40, it is judged whether the high temperature side interface temperature Tbh is higher than the upper limit temperature Tmax or not. On the other hand, in the working example apparatus 102, it is judged whether the high temperature side interface temperature Tbh is higher than the upper limit temperature Tmax or not based on the output power value P detected by the output detection device 20, etc.

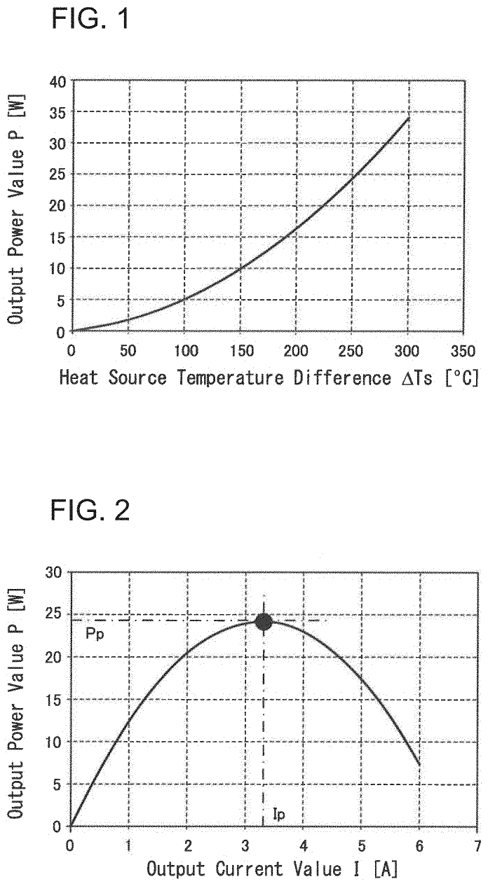

Also in the working example apparatus 102, as explained referring to the graph of FIG. 1, the output power value P from the thermoelectric generation module 10M becomes larger as the heat source temperature difference ΔTs becomes larger, unless problems, such as damage of the thermoelectric conversion element 10E arise, for example. Furthermore, also in the working example apparatus 102, as explained referring to the graph of FIG. 2, the output power value P from the thermoelectric generation module 10M becomes the maximum value (maximum output power value Pp) at a specific current value Ip. In other words, the output power value P becomes larger as the output current value I becomes larger in a region where the output current value I is less than this specific output current value Ip, and the output power value P becomes smaller as the output current value I becomes larger in a region where the output current value I is this specific output current value Ip or more. In addition, also in the working example apparatus 102, as explained referring to the graph of FIG. 8, when the output current value I is increased, the temperature of the interface on the high temperature heat source 10H side of the thermoelectric conversion element 10E which constitutes the thermoelectric generation module 10M (high temperature side interface temperature Tbh) falls in association with it.

The above-mentioned characteristics of the thermoelectric generation module 10M and the upper limit of the high temperature side interface temperature Tbh (upper limit temperature Tmax) changes depending on materials of the thermoelectric semiconductors (10N and 10P) which constitute the thermoelectric generation module 10M and a configuration of the thermoelectric conversion element 10E formed by the thermoelectric semiconductors, etc. In the working example apparatus 102, the upper limit temperature Tmax of the thermoelectric generation module 10M is 280° C., and the control part 50 is configured so as to perform the above-mentioned maximum power point tracking (MPPT) as the ordinary control routine when the high temperature side interface temperature Tbh is 280° C. or less. Moreover, in the following explanation, it is assumed that a temperature of the low temperature heat source 10C of the thermoelectric conversion element 10E which constitute the thermoelectric generation module 10M (low temperature heat source temperature Tc) is always maintained at a constant temperature of 30° C.

Here, control of the high temperature side interface temperature Tbh performed in the working example apparatus 102 will be explained in detail, referring to graphs of FIG. 16 and FIG. 17. A solid line curve in FIG. 16 represents a relation between the output current value I and the output power value P in a state (state A) where the high temperature side interface temperature Tbh is equal to the upper limit temperature Tmax (280° C.). Since the low temperature heat source temperature Tc is constant at 30° C. as mentioned above, the heat source temperature difference ΔTs at this time is 250° C. In the working example apparatus 102, as mentioned above, when the high temperature side interface temperature Tbh is 280° C. or less, the MPPT is performed as the ordinary control routine. As a result, the output current value I is adjusted to be about 3.3 A (Imax), and the output power Pa of about 24 W (critical output power value Pmax) is output. This state A corresponds to a point A in the graph (time chart) of FIG. 17.

On the other hand, a broken line curve in FIG. 16 represents a relation between the output current value I and the output power value P in a state (state B) where a temperature of exhaust gas from an internal combustion engine as the high temperature heat source 10H (namely, the high temperature heat source temperature Th) rises due to some causes, such as high load operation, and the high temperature side interface temperature Tbh has reached a temperature higher than the upper limit temperature Tmax (280° C.), as shown by an arrow F1 in the graph of FIG. 16. The interface temperature difference ΔTb increases in association with the fact that the high temperature side interface temperature Tbh has risen to a temperature higher than the upper limit temperature Tmax. As a result, the output power value P has increased from Pa (namely, Pmax=about 24 W) to Pb (about 32.5 W) even though the output current value I at this time is equal to the output current I in the above-mentioned state A (=Imax). Thus, even when the output current value I does not change, the high temperature side interface temperature Tbh changes and thereby the output power value P is changed.

Namely, the output power Pb in the above-mentioned state B is larger than the critical output power value Pmax. The critical output power value Pmax is the maximum power Pp obtained when the high temperature side interface temperature Tbh is equal to the upper limit temperature Tmax, as mentioned above. Therefore, a fact that the output power value P at a certain time point is larger than the critical output power value Pmax means that the high temperature side interface temperature Tbh is higher than the upper limit temperature Tmax.

Then, the DC-DC converter as the output adjustment device 30 and the control part 50 increases the output current value I from the thermoelectric generation module 10M in accordance with the above-mentioned cooling control routine. In this example, the output current I is increased from about 3.3 A to about 7 A as shown by an arrow F2 in the graph of FIG. 16 (state C).

By the above, a thermal conductivity of the thermoelectric conversion element 10E which constitutes the thermoelectric generation module 10M becomes larger, and a movement of heat from an interface on a side of the high temperature heat source (high temperature side interface Bh) to an interface on a side of the low temperature heat source (low temperature side interface Bc) is promoted. As a result, as shown at a point C in the time chart of FIG. 17, the high temperature side interface temperature Tbh falls, and the low temperature side interface temperature Tbc rises. Namely, since the interface temperature difference ΔTb becomes smaller, the output power value P from the thermoelectric generation module 10M falls to Pc (about 22.5 W). However, as shown in FIG. 17, the above-mentioned changes of the high temperature side interface temperature Tbh and the low temperature side interface temperature Tbc result from the movement of heat between the high temperature side interface Bh and the low temperature side interface Bc of the thermoelectric conversion element 10E, and does not substantially affect the high temperature heat source temperature Th and the low temperature heat source temperature Tc. Namely, the heat source temperature difference ΔTs does not change substantially.

Thereafter, even when the temperature of the exhaust as falls due to decrease in an operating load of the internal combustion engine, etc., for example, and the temperature Th of the high temperature heat source 10H falls, the output current value I does not change and remains at the large value in the state C and the thermal conductivity of the thermoelectric conversion element 10E also remains large. Therefore, since quantity of heat which moves to the interface Bc on the side of the low temperature heat source from the interface Bh on the side of the high temperature heat source also remains large, the high temperature side interface temperature Tbh falls and reaches a temperature lower than the upper limit temperature Tmax (280° C.) in due course, as shown at a point D in the time chart of FIG. 17. As a result, the interface temperature-difference ΔTb becomes smaller further, and the output power value P also becomes smaller further.

When the high temperature side interface temperature Tbh falls to less than the upper limit temperature Tmax as mentioned above, the DC-DC converter 30 as the control part 50 controls the output adjustment device 30 in accordance with the ordinary control routine to control the output current value I. Specifically, the DC-DC converter 30 is configured so as to perform output maximize control that is control in which the DC-DC converter 30 as a output adjustment device is controlled to change the output current value I such that the output power value P becomes the maximum (in this example, the maximum power point tracking (MPPT)). As a result, the high temperature side interface temperature Tbh returns close to the upper limit temperature Tmax in due course as shown at a point E in the time chart of FIG. 17. In association with this, the output current value I returns to Imax and the output power value P returns to Pa (=Pmax) as shown by an arrow F3 in the graph of FIG. 16. Namely, the state returns to the state A from the state C.

As the above, in accordance with working example apparatus 102, when it is judged that the high temperature side interface temperature Tbh is higher than the upper limit temperature Tmax based on the output current value I and the output power value P from the thermoelectric generation module 10M detected by the output detection device 20 and the first characteristic data stored in the storage unit which the control part 50 comprises, the cooling control in which the output current value I is increased by the output adjustment device 30 to lower the temperature of the interface on the high temperature heat source 10H side of the thermoelectric generation module 10M (high temperature side interface temperature Tbh) is reduced is performed. On the other hand, when the high temperature side interface temperature Tbh is judged to be the upper limit temperature Tmax or less, the output maximize control that is control in which the output adjustment device 30 is controlled to change the output current value I such that the output power value P becomes the maximum (in this example, MPPT) is performed.

In accordance with the above, also in the working example apparatus 102, the thermoelectric generation module 10M can be worked at high generating efficiency while maintaining the high temperature side interface temperature Tbh at the upper limit temperature Tmax or less and preventing damage of the electrothermal power generation element 10E.

Although some the embodiments and working examples which have specific configurations have been explained, sometimes referring to the drawings, as the above for the purpose of explaining the present invention, it should not be interpreted that the scope of the present invention is limited to these exemplary embodiments and working examples, and it is needless to say that it is possible to add modifications properly within the limits of matters described in the claims and specification.

### REFERENCE SIGNS LIST

10M: Thermoelectric Generation Module, 10E: Thermoelectric Conversion Element, 10N and 10P: Thermoelectric Semiconductor, 10H: High Temperature Heat Source, 10C: Low Temperature Heat Source, 11H: Support Substrate (High Temperature Heat Source Side), 11C: Support Substrate (Low Temperature Heat Source Side), 12H: Electrode (High Temperature Heat Source Side), 12C: Electrode (Low Temperature Heat Source Side), 20: Output Detection Device, 30: Output Adjustment Device (DC-DC Converter), 40: Temperature Detection Device, 40x and 40y: Thermocouple, 50: Control Part, 100: Thermoelectric Generation Apparatus (First Apparatus), 101 and 102: Thermoelectric Generation Apparatus (Working Example Apparatus) and 200: Power Supply Destination (Load).

1-9. (canceled)

10. A thermoelectric generation apparatus comprising:
a thermoelectric generation module comprising a thermoelectric conversion element which generates electricity by a heat source temperature difference that is a temperature difference between a high temperature heat source and a low temperature heat source,
an output adjustment device which changes an output current value that is magnitude of electric current output from said thermoelectric generation module and/or an output voltage value that is magnitude of electric voltage output from said thermoelectric generation module, and
a control part which controls said output adjustment device to control said output current value and/or said output voltage value; wherein:
said thermoelectric generation apparatus further comprises a temperature detection device which detects a temperature measuring point temperature that is a temperature of a temperature measuring point that is at least one position included in any of said high temperature heat source, said low temperature heat source and said thermoelectric generation module, and
said control part is configured so as to control said output adjustment device to increase said output current value or decrease said output voltage value when a high temperature side interface temperature that is a temperature of a high temperature side interface that is an interface on said high temperature heat source side of said thermoelectric conversion element is judged to be higher than a predetermined upper limit temperature at least based on said temperature measuring point temperature, and
said temperature detection device is configured so as to respectively detect a first temperature measuring point temperature and second temperature measuring point temperature that are temperatures of a first temperature measuring point and second temperature measuring point that are two of said temperature measuring points located a predetermined interval apart from each other in a heat flow direction that is a flow direction of heat moving to said low temperature heat source from said high temperature heat source via said thermoelectric generation module, and
said control part is configured so as to;
determine penetrating heat quantity that is quantity of heat moving to said low temperature heat source from said high temperature heat source via said thermoelectric generation module, based on a difference between said first temperature measuring point temperature and said second temperature measuring point temperature, a thermal conductivity and heat passage area of a region between said first temperature measurinngpoint and said second temperature measuring point in said heat flow direction, and a distance between said first temperature measuring point and said second temperature measuring point in said heat flow direction,
determine said high temperature side interface temperature, based on said first temperature measuring point temperature and/or said second temperature measuring point temperature, thermal conductivities and heat passage areas of regions to said first temperature measuring point and/or said second temperature measuring point from said high temperature side interface in said heat flow direction, said penetrating heat quantity and distances to said first temperature measuring point and/or said second temperature measuring point from said high temperature side interface in said heat flow direction, and
judge whether said high temperature side interface temperature is higher than said upper limit temperature or not.

11. A thermoelectric generation apparatus comprising:
a thermoelectric generation module comprising a thermoelectric conversion element which generates electricity by a heat source temperature difference that is a temperature difference between a high temperature heat source and a low temperature heat source,
an output adjustment device which changes an output current value that is magnitude of electric current output from said thermoelectric generation module and/or an output voltage value that is magnitude of electric voltage output from said thermoelectric generation module, and
a control part which controls said output adjustment device to control said output current value and/or said output voltage value; wherein:
said thermoelectric generation apparatus further comprises a temperature detection device which detects a temperature measuring point temperature that is a temperature of a temperature measuring point that is at least one position included in any of said high temperature heat source, said low temperature heat source and said thermoelectric generation module, and
said control part is configured so as to control said output adjustment device to increase said output current value or decrease said output voltage value when a high temperature side interface temperature that is a temperature of a high temperature side interface that is an interface on said high temperature heat source side of said thermoelectric conversion element is judged to be higher than a predetermined upper limit temperature at least based on said temperature measuring point temperature, and
a low temperature side temperature measuring point temperature that is a temperature of a low temperature side temperature measuring point that is at least one position included in said low temperature heat source is maintained at a constant temperature, and
said control part is configured so as to;
determine penetrating heat quantity that is quantity of heat moving to said low temperature heat source from said high temperature heat source via said thermoelectric generation module, based on a difference between said temperature measuring point temperature and said low temperature side temperature measuring point temperature, a thermal conductivity and heat passage area of a region between said temperature measuring point and said low temperature side temperature measuring point in a heat flow direction that is a flow direction of heat moving to said low temperature heat source from said high temperature heat source via said thermoelectric generation module, and a distance between said temperature measuring point and said low temperature side temperature measuring point in said heat flow direction,
determine said high temperature side interface temperature, based on said temperature measuring point temperature, thermal conductivities and heat passage areas of regions to said temperature measuring point and/or said low temperature side temperature measuring point from said high temperature side interface in said heat flow direction, said penetrating heat quantity and distances to said temperature measuring point and/or said low temperature side temperature measuring point from said high temperature side interface in said heat flow direction, and
judge whether said high temperature side interface temperature is higher than said upper limit temperature or not.

12. A thermoelectric generation apparatus comprising:
a thermoelectric generation module comprising a thermoelectric conversion element which generates electricity by a heat source temperature difference that is a temperature difference between a high temperature heat source and a low temperature heat source,
an output adjustment device which changes an output current value that is magnitude of electric current output from said thermoelectric generation module and/or an output voltage value that is magnitude of electric voltage output from said thermoelectric generation module, and
a control part which controls said output adjustment device to control said output current value and/or said output voltage value; wherein:
said thermoelectric generation apparatus further comprises a temperature detection device which detects a temperature measuring point temperature that is a temperature of a temperature measuring point that is at least one position included in any of said high temperature heat source, said low temperature heat source and said thermoelectric generation module, and
said control part is configured so as to control said output adjustment device to increase said output current value or decrease said output voltage value when a high temperature side interface temperature that is a temperature of a high temperature side interface that is an interface on said high temperature heat source side of said thermoelectric conversion element is judged to be higher than a predetermined upper limit temperature at least based on said temperature measuring point temperature, and
said thermoelectric generation apparatus further comprises an output detection device which detects output related values that are a set of a plurality of detection values consisting of an output power value that is magnitude of electric power output from said thermoelectric generation module, an output current value that is magnitude of electric current output from said thermoelectric generation module and/or an output voltage value that is magnitude of electric voltage output from said thermoelectric generation module, and
said control part has previously stored first characteristic data that is data representing a relation between said heat source temperature difference and said output related values,
said control part is configured so as to;
determine said penetrating heat quantity, based on said heat source temperature difference determined based on said first characteristic data from said output related values detected by said output detection device, a thermal conductivity and heat passage area of a region where said heat source temperature difference is produced, and a length of said region where said heat source temperature difference is produced in a heat flow direction that is a flow direction of heat moving to said low temperature heat source from said high temperature heat source via said thermoelectric generation module,
determine said high temperature side interface temperature, based on said temperature measuring point temperature, a thermal conductivity and heat passage area of a region between said temperature measuring point and said high temperature side interface in said heat flow direction, said penetrating heat quantity and a distance between said temperature measuring point and said high temperature side interface in said heat flow direction, and
judge whether said high temperature side interface temperature is higher than said upper limit temperature or not.

13. A thermoelectric generation apparatus comprising:
a thermoelectric generation module comprising a thermoelectric conversion element which generates electricity by a heat source temperature difference that is a temperature difference between a high temperature heat source and a low temperature heat source,
an output adjustment device which changes an output current value that is magnitude of electric current output from said thermoelectric generation module and/or an output voltage value that is magnitude of electric voltage output from said thermoelectric generation module, and
a control part which controls said output adjustment device to control said output current value and/or said output voltage value; wherein:
said thermoelectric generation apparatus further comprises a temperature detection device which detects a temperature measuring point temperature that is a temperature of a temperature measuring point that is at least one position included in any of said high temperature heat source, said low temperature heat source and said thermoelectric generation module, and
said control part is configured so as to control said output adjustment device to increase said output current value or decrease said output voltage value when a high temperature side interface temperature that is a temperature of a high temperature side interface that is an interface on said high temperature heat source side of said thermoelectric conversion element is judged to be higher than a predetermined upper limit temperature at least based on said temperature measuring point temperature, and
said thermoelectric generation apparatus further comprises an output detection device which detects an output related values that are a set of a plurality of detection values consisting of an output power value that is magnitude of electric power output from said thermoelectric generation module, an output current value that is magnitude of electric current output from said thermoelectric generation module and/or an output voltage value that is magnitude of electric voltage output from said thermoelectric generation module, and
said control part is configured so as to;
previously store first characteristic data that is data representing a relation between said heat source temperature difference and said output related values,
determine said penetrating heat quantity, based on said heat source temperature difference determined based on said first characteristic data from said output related values detected by said output detection device, a thermal conductivity and heat passage area of a region where said heat source temperature difference is produced, and a length of said region where said heat source temperature difference is produced in a heat flow direction that is a flow direction of heat moving to said low temperature heat source from said high temperature heat source via said thermoelectric generation module,
determine upper limit penetrating heat quantity that is quantity of heat moving to said high temperature side interface from said temperature measuring point when said high temperature side interface temperature is equal to said upper limit temperature, based on a difference between said temperature measuring point temperature and said high temperature side interface temperature, a thermal conductivity and heat passage area of a region between said temperature measuring point and said high temperature side interface in said heat flow direction and a distance between said temperature measuring point and said high temperature side interface in said heat flow direction when said high temperature side interface temperature is equal to said upper limit temperature, and
judge that said high temperature side interface temperature is higher than said upper limit temperature when said penetrating heat quantity is smaller than said upper limit penetrating heat quantity in a case where said temperature measuring point is closer to said high temperature heat source than said high temperature side interface, and judge that said high temperature side interface temperature is higher than said upper limit temperature when said penetrating heat quantity is larger than said upper limit penetrating heat quantity in a case where said temperature measuring point is closer to said low temperature heat source than said high temperature side interface.

14. A thermoelectric generation apparatus comprising:
a thermoelectric generation module comprising a thermoelectric conversion element which generates electricity by a heat source temperature difference that is a temperature difference between a high temperature heat source and a low temperature heat source,
an output adjustment device which changes an output current value that is magnitude of electric current output from said thermoelectric generation module and/or an output voltage value that is magnitude of electric voltage output from said thermoelectric generation module, and
a control part which controls said output adjustment device to control said output current value and/or said output voltage value; wherein:
said thermoelectric generation apparatus further comprises a temperature detection device which detects a temperature measuring point temperature that is a temperature of a temperature measuring point that is at least one position included in any of said high temperature heat source, said low temperature heat source and said thermoelectric generation module, and
said control part is configured so as to control said output adjustment device to increase said output current value or decrease said output voltage value when a high temperature side interface temperature that is a temperature of a high temperature side interface that is an interface on said high temperature heat source side of said thermoelectric conversion element is judged to be higher than a predetermined upper limit temperature at least based on said temperature measuring point temperature, and
a low temperature side temperature measuring point temperature that is a temperature of a low temperature side temperature measuring point that is at least one position included in said low temperature heat source is maintained at a fixed temperature,
said thermoelectric generation apparatus further comprises an output detection device which detects an output related values that are a set of a plurality of detection values consisting of an output power value that is magnitude of electric power output from said thermoelectric generation module, an output current value that is magnitude of electric current output from said thermoelectric generation module and/or an output voltage value that is magnitude of electric voltage output from said thermoelectric generation module,
said control part has previously stored first characteristic data that is data representing a relation between said heat source temperature difference and said output related values,
said control part is configured so as to;
determine said heat source temperature difference based on said first characteristic data from said output related values detected by said output detection device,
determine upper limit penetrating heat quantity that is quantity of heat moving to said high temperature side interface from said temperature measuring point when said high temperature side interface temperature is equal to said upper limit temperature, based on a difference between said temperature measuring point temperature and said high temperature side interface temperature, a thermal conductivity and heat passage area of a region between said temperature measuring point and said high temperature side interface in a heat flow direction that is a flow direction of heat moving to said low temperature heat source from said high temperature heat source via said thermoelectric generation module and a distance between said temperature measuring point and said high temperature side interface in said heat flow direction when said high temperature side interface temperature is equal to said upper limit temperature,
determine an upper limit heat source temperature difference that is a temperature difference between said high temperature heat source and said low temperature heat source when said high temperature side interface temperature is equal to said upper limit temperature, based on said upper limit penetrating heat quantity, a thermal conductivity and heat passage area of a region where said heat source temperature difference is produced, and a length of said region where said heat source temperature difference is produced in said heat flow direction, and
judge that said high temperature side interface temperature is higher than said upper limit temperature when said heat source temperature difference is larger than said upper limit heat source temperature difference.

15. A thermoelectric generation apparatus comprising:
a thermoelectric generation module comprising a thermoelectric conversion element which generates electricity by a heat source temperature difference that is a temperature difference between a high temperature heat source and a low temperature heat source,
an output adjustment device which changes an output current value that is magnitude of electric current output from said thermoelectric generation module and/or an output voltage value that is magnitude of electric voltage output from said thermoelectric generation module, and
a control part which controls said output adjustment device to control said output current value and/or said output voltage value; wherein:
said thermoelectric generation apparatus further comprises a temperature detection device which detects a temperature measuring point temperature that is a temperature of a temperature measuring point that is at least one position included in any of said high temperature heat source, said low temperature heat source and said thermoelectric generation module, and
said control part is configured so as to control said output adjustment device to increase said output current value or decrease said output voltage value when a high temperature side interface temperature that is a temperature of a high temperature side interface that is an interface on said high temperature heat source side of said thermoelectric conversion element is judged to be higher than a predetermined upper limit temperature at least based on said temperature measuring point temperature, and
a low temperature side temperature measuring point temperature that is a temperature of a low temperature side temperature measuring point that is at least one position included in said low temperature heat source is maintained at a fixed temperature,
said thermoelectric generation apparatus further comprises an output detection device which detects an output related values that are a set of a plurality of detection values consisting of an output power value that is magnitude of electric power output from said thermoelectric generation module, an output current value that is magnitude of electric current output from said thermoelectric generation module and/or an output voltage value that is magnitude of electric voltage output from said thermoelectric generation module,
said control part has previously stored first characteristic data that is data representing a relation between said heat source temperature difference and said output related values,
said control part is configured so as to;
determine upper limit penetrating heat quantity that is quantity of heat moving to said high temperature side interface from said temperature measuring point when said high temperature side interface temperature is equal to said upper limit temperature, based on a difference between said temperature measuring point temperature and said high temperature side interface temperature, a thermal conductivity and heat passage area of a region between said temperature measuring point and said high temperature side interface in a heat flow direction that is a flow direction of heat moving to said low temperature heat source from said high temperature heat source via said thermoelectric generation module and a distance between said temperature measuring point and said high temperature side interface in said heat flow direction when said high temperature side interface temperature is equal to said upper limit temperature,
determine an upper limit heat source temperature difference that is a temperature difference between said high temperature heat source and said low temperature heat source when said high temperature side interface temperature is equal to said upper limit temperature, based on said upper limit penetrating heat quantity, a thermal conductivity and heat passage area of a region where said heat source temperature difference is produced, and a length of said region where said heat source temperature difference is produced in said heat flow direction,
determine an upper limit output power value that is magnitude of electric power output from said thermoelectric generation module when said heat source temperature difference is equal to said upper limit heat source temperature difference and said output current value and/or said output voltage value are equal to said output current value and/or said output voltage value detected by said output detection device, based on said first characteristic data, and
judge that said high temperature side interface temperature is higher than said upper limit temperature when said output power value detected by said output detection device is larger than said upper limit output power value.

16. A thermoelectric generation apparatus comprising:
a thermoelectric generation module comprising a thermoelectric conversion element which generates electricity by a heat source temperature difference that is a temperature difference between a high temperature heat source and a low temperature heat source,
an output adjustment device which changes an output current value that is magnitude of electric current output from said thermoelectric generation module and/or an output voltage value that is magnitude of electric voltage output from said thermoelectric generation module, and
a control part which controls said output adjustment device to control said output current value and/or said output voltage value; wherein:
said thermoelectric generation apparatus further comprises a temperature detection device which detects a temperature measuring point temperature that is a temperature of a temperature measuring point that is at least one position included in any of said high temperature heat source, said low temperature heat source and said thermoelectric generation module, and
said control part is configured so as to control said output adjustment device to increase said output current value or decrease said output voltage value when a high temperature side interface temperature that is a temperature of a high temperature side interface that is an interface on said high temperature heat source side of said thermoelectric conversion element is judged to be higher than a predetermined upper limit temperature at least based on said temperature measuring point temperature, and
a low temperature side temperature measuring point temperature that is a temperature of a low temperature side temperature measuring point that is at least one position included in said low temperature heat source is maintained at a fixed temperature,
said thermoelectric generation apparatus further comprises an output detection device which detects an output related values that are a set of a plurality of detection values consisting of an output power value that is magnitude of electric power output from said thermoelectric generation module, an output current value that is magnitude of electric current output from said thermoelectric generation module and/or an output voltage value that is magnitude of electric voltage output from said thermoelectric generation module,
said control part has previously stored first characteristic data that is data representing a relation between said heat source temperature difference and said output related values,
said control part is configured so as to;
determine upper limit penetrating heat quantity that is quantity of heat moving to said high temperature side interface from said temperature measuring point when said high temperature side interface temperature is equal to said upper limit temperature, based on a difference between said temperature measuring point temperature and said high temperature side interface temperature, a thermal conductivity and heat passage area of a region between said temperature measuring point and said high temperature side interface in a heat flow direction that is a flow direction of heat moving to said low temperature heat source from said high temperature heat source via said thermoelectric generation module and a distance between said temperature measuring point and said high temperature side interface in said heat flow direction when said high temperature side interface temperature is equal to said upper limit temperature,
determine an upper limit heat source temperature difference that is a temperature difference between said high temperature heat source and said low temperature heat source when said high temperature side interface temperature is equal to said upper limit temperature, based on said upper limit penetrating heat quantity, a thermal conductivity and heat passage area of a region where said heat source temperature difference is produced, and a length of said region where said heat source temperature difference is produced in said heat flow direction, and
judge that said high temperature side interface temperature is higher than said upper limit temperature, when upper limit output related values that are output current and/or output voltage output from said thermoelectric generation module is not determined based on said first characteristic data in a case where said heat source temperature difference is equal to said upper limit heat source temperature difference and said output power value is equal to said output power value detected by said output detection device, or when said upper limit output related values are determined based on said first characteristic data and said output current value and/or said output voltage value detected by said output detection device are larger or smaller than any of said upper limit output related values.

17. The thermoelectric generation apparatus, according to claim 12, wherein:
said control part is configured so as to perform output maximize control that is control in which said output adjustment device is controlled to change said output current value and/or said output voltage value such that said output power value becomes the maximum, when said high temperature side interface temperature is judged to be said upper limit temperature or less, and
said control part has stored second characteristic data that is data representing a relation between said heat source temperature difference when performing said output maximize control and an index detection value that is at least one detection value of the plurality of said detection values included in said output related values, as said first characteristic data,
said control part is configured so as to;
determine said heat source temperature difference based on said second characteristic data from said index detection value detected by said output detection device, and
stop execution of said output maximize control and control said output adjustment device to increase said output current value or decrease said output voltage value when said high temperature side interface temperature is judged to be higher than said upper limit temperature.
